(19) United States
(12) Patent Application Publication
(10) Pub. No.: US 2026/0173531 A1
(43) Pub. Date: Jun. 18, 2026

(54) DISPLAY PANEL AND ELECTRONIC DEVICE

(71) Applicant: Tianma Advanced Display Technology Institute (Xiamen) Co.,Ltd., Xiamen (CN)

(72) Inventors: Zhimin ZHOU, Xiamen (CN); Zhenyu JIA, Xiamen (CN); Yingteng ZHAI, Xiamen (CN); Wenxin JIANG, Xiamen (CN); Tianyi WU, Xiamen (CN)

(21) Appl. No.: 19/213,072

(22) Filed: May 20, 2025

(30) Foreign Application Priority Data
Dec. 18, 2024 (CN) 202411870027.6

(51) Int. Cl. H10D 86/40; G09G 3/32; H10D 86/60

(52) U.S. Cl. CPC H10D 86/441; G09G 3/32; H10D 86/60; G09G 2300/0426; G09G 2300/0852; G09G 2310/08

(57) ABSTRACT

A display panel, a method for fabricating a display panel and a display device are provided. The display panel includes a substrate; and a first active layer, a first gate metal layer, a second active layer, a second gate metal layer, a first insulation layer and a second insulation layer disposed on one side of the substrate. The first insulation layer is located between the first active layer and the first gate metal layer; the second insulation layer is located between the second active layer and the second gate metal layer; the first insulation layer is made of a first type of insulation material; the second insulation layer is made of a second type of insulation material; and an oxygen content of the first type of insulation material is less than an oxygen content of the second type of insulation material.

### CROSS-REFERENCE TO RELATED APPLICATION

This application claims the priority of Chinese Patent Application No. 202411870027.6, filed on Dec. 18, 2024, the content of which is incorporated by reference/in its entirety.

### TECHNICAL FIELD

The present disclosure generally relates to the field of display technologies and, more particularly, relates to a display panel and a display device.

### BACKGROUND

With the continuous improvement of display technologies, people's requirements for display devices are also constantly increasing. Among various display technologies, self-luminous display devices have been widely used in various electronic devices including computers, mobile phones and other electronic products due to their advantages of self-luminescence, light weight, low power consumption, high contrast, high color gamut, and flexible display. The self-luminous elements in self-luminous display devices are generally organic light-emitting diodes (OLED), quantum dot light-emitting diodes (QLED), micro light-emitting diodes (Micro LED), etc. In actual display panel, the pixel driving circuit generally outputs a driving current to drive the light-emitting element to emit light, so that the display device can achieve the purpose of displaying the picture.

Therefore, the pixel driving circuit is one of the important projects in the research and development of display devices. The present disclosed display panels and electronic devices are direct to effectively solve the existing technical problems, optimize the circuit layout of the pixel driving circuit, and other problems in the arts.

### SUMMARY

One aspect of the present disclosure provides a display panel. The display panel includes a pixel driving circuit. The pixel driving circuit includes a driving transistor and a first transistor, one terminal of the first transistor being connected to a gate of the driving transistor through a gate device connection line. The display panel also includes a plurality of signal transmission lines providing control signals or input signals for the pixel driving circuit. A signal transmission line of the plurality of signal transmission lines extends in a first direction; the gate device connection line includes a first connection line portion extending in a second direction; in a direction perpendicular to a plane where the display panel is located, the first connection line portion at least partially overlaps with at least two signal transmission lines of the plurality of signal transmission line; and the first direction intersects with the second direction.

Another aspect of the present disclosure provides an electronic device. The electronic device includes a display panel. The display panel includes a pixel driving circuit. The pixel driving circuit includes a driving transistor and a first transistor, one terminal of the first transistor being connected to a gate of the driving transistor through a gate device connection line. The display panel also includes a plurality of signal transmission lines providing control signals or input signals for the pixel driving circuit. A signal transmission line of the plurality of signal transmission lines extends in a first direction; the gate device connection line includes a first connection line portion extending in a second direction; in a direction perpendicular to a plane where the display panel is located, the first connection line portion at least partially overlaps with at least two signal transmission lines of the plurality of signal transmission line; and the first direction intersects with the second direction.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various embodiments of the present disclosure;

FIG. 2 illustrates another exemplary display panel according to various embodiments of the present disclosure;

FIG. 3 illustrates a partial circuit diagram of an exemplary pixel driving circuit according to various embodiments of the present disclosure;

FIG. 4 illustrates an FF′-sectional view in FIG. 3;

FIG. 5 illustrates a partial circuit diagram of another exemplary pixel driving circuit according to various embodiments of the present disclosure;

FIG. 6 illustrates a GG′-sectional view in FIG. 5;

FIG. 7 illustrates a partial circuit diagram of another exemplary pixel driving circuit according to various embodiments of the present disclosure;

FIG. 8 illustrates another exemplary display panel according to various embodiments of the present disclosure;

FIG. 9 illustrates another exemplary display panel according to various embodiments of the present disclosure;

FIG. 10 illustrates another exemplary display panel according to various embodiments of the present disclosure;

FIG. 11 illustrates a partial circuit diagram of another exemplary pixel driving circuit according to various embodiments of the present disclosure;

FIG. 12 illustrates an HH′-sectional view in FIG. 12;

FIG. 13 illustrates an exemplary overlap structure of a device connection line and a signal transmission line according to various embodiments of the present disclosure;

FIG. 14 illustrates another exemplary overlap structure of a device connection line and a signal transmission line according to various embodiments of the present disclosure;

FIG. 15 illustrates another exemplary overlap structure of a device connection line and a signal transmission line according to various embodiments of the present disclosure;

FIG. 16 illustrates another exemplary overlap structure of a device connection line and a signal transmission line according to various embodiments of the present disclosure;

FIG. 17 illustrates an AA′, BB′ and CC′-sectional in FIG. 16;

FIG. 18 illustrates another AA′, BB′ and CC′-sectional in FIG. 16;

FIG. 19 illustrates another exemplary overlap structure of a device connection line and a signal transmission line according to various embodiments of the present disclosure;

FIG. 20 illustrates another exemplary overlap structure of a device connection line and a signal transmission line according to various embodiments of the present disclosure;

FIG. 21 illustrates another exemplary overlap structure of a device connection line and a signal transmission line according to various embodiments of the present disclosure;

FIG. 22 illustrates another exemplary overlap structure of a device connection line and a signal transmission line according to various embodiments of the present disclosure;

FIG. 23 illustrates another exemplary overlap structure of a device connection line and a signal transmission line according to various embodiments of the present disclosure;

FIG. 24 illustrates another exemplary overlap structure of a device connection line and a signal transmission line according to various embodiments of the present disclosure;

FIG. 25 illustrates another exemplary overlap structure of a device connection line and a signal transmission line according to various embodiments of the present disclosure;

FIG. 26 illustrates another exemplary overlap structure of a device connection line and a signal transmission line according to various embodiments of the present disclosure;

FIG. 27 illustrates another exemplary overlap structure of a device connection line and a signal transmission line according to various embodiments of the present disclosure;

FIG. 28 is a DD′ and EE′-sectional view in FIG. 27;

FIG. 29 illustrates an exemplary equivalent circuit diagram according to various embodiments of the present disclosure;

FIG. 30 illustrates an exemplary sequence diagram according to various disclosed embodiments of the present disclosure;

FIG. 31 illustrates a layout of an exemplary pixel driving circuit according to various embodiments of the present disclosure;

FIG. 32 illustrates a layout of another exemplary pixel driving circuit according to various embodiments of the present disclosure; and

FIG. 33 illustrates an exemplary electronic device according to various embodiments of the present disclosure.

### DETAILED DESCRIPTION

The following will be combined with the drawings in the embodiments of the present disclosure to clearly and completely describe the technical solutions in the embodiments of the present disclosure. Obviously, the described embodiments are only part of the embodiments of the present disclosure, not all of the embodiments. Based on the embodiments in the present disclosure, all other embodiments obtained by ordinary technicians in the field without creative work are within the scope of protection of the present disclosure.

As described in the background technology, with the continuous improvement of display technology, people's requirements for display devices are also constantly improving. Among various display technologies, self-luminous display devices have been widely used in various electronic devices including computers, mobile phones and other electronic products due to their advantages of self-luminescence, lightness, low power consumption, high contrast, high color gamut, and flexible display. The self-luminous elements in the self-luminous display devices are generally organic light-emitting diodes, quantum dot light-emitting diodes, micro light-emitting diodes, etc. In actual display, the pixel driving circuit generally outputs a driving current to drive the light-emitting element to emit light, so that the display device can achieve the purpose of picture display. Therefore, the pixel driving circuit is one of the important projects in the research and development of the display device.

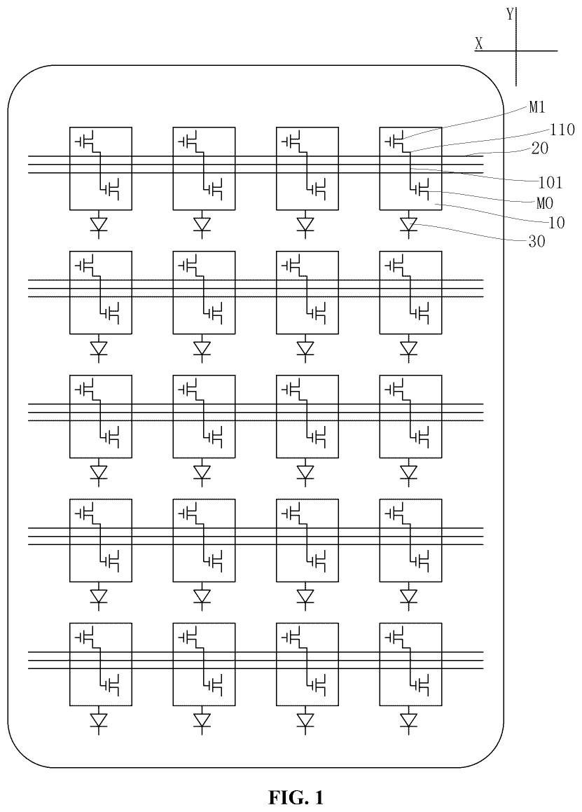

In view of this, the present disclosure provides a display panel and an electronic device, which may effectively solve the existing technical problems, optimize the circuit layout of the pixel driving circuit, and improve the performance of the display panel. To achieve the above purpose, the technical solution provided by the embodiments of the present disclosure is as follows, and the technical solution provided by the embodiments of the present disclosure is described in detail in conjunction with FIGS. 1-33. It should be noted that the overlapping or crossing characteristics between the large partial circuits described below in the embodiment of the present disclosure are all characteristics of insulating overlap or insulating cross in the direction perpendicular to the plane where the display panel is located (except for the case of structural multiplex when overlapping), such as an isolation film may be provided between the two overlapping or crossing circuits to achieve the insulation.

FIG. 1 illustrates an exemplary display panel according to various embodiments of the present disclosure. As shown in FIG. 1, the display panel may include a pixel driving circuit 10. The pixel driving circuit 10 may include a driving transistor M0 and a first transistor M1. One terminal of the first transistor M1 may be connected to the gate of the driving transistor M0 through a gate device connection line 110.

In one embodiment, the gate device connection line 110 provided in the present disclosure may be directly connected to one terminal of the first transistor M1 and the gate of the driving transistor M0, or the gate device connection line 110 may be indirectly electrically connected to one terminal of the first transistor M1 and directly electrically connected to the gate of the driving transistor M0; or the gate device connection line 110 may be directly electrically connected to one terminal of the first transistor M1 and indirectly electrically connected to the gate of the driving transistor M0.

The display panel may also include a plurality of signal transmission lines 20, which may provide control signals or input signals for the pixel driving circuit 10, and the signal transmission lines 20 may extend in the first direction X. The gate device connection line 110 may include a first connection line portion 101 extending in the second direction Y. In the direction perpendicular to the plane where the display panel is located, the first connection line portion 101 may at least partially overlap with at least two signal transmission lines 20. The first direction X and the second direction Y may intersect. In some embodiments, the first direction X and the second direction Y provided in the present disclosure may be perpendicular to each other.

Specifically, the display panel may include a substrate (not shown), and a plurality of pixel driving circuits 10 arranged on the substrate. One pixel driving circuit 10 may be electrically connected to at least one light-emitting element 30. The light-emitting element 30 may be a light-emitting diode, such as a micro LED or a mini LED, etc., and may also be an organic light-emitting diode, which is not specifically limited in the present disclosure. In addition, a driving circuit (not shown) for providing a control signal and a signal line (not shown) for providing a reference voltage and other similar input signals may also be arranged on the substrate. At the same time, a plurality of signal transmission lines 20 may be arranged to match the driving circuits and the signal lines. The control signal output by the driving circuit and the input signal transmitted by the signal line may be transmitted to each pixel driving circuit 10 through the signal transmission line 20, so as to control the pixel driving circuit 10 to light up or extinguish the light-emitting element 30 according to the set timing during the operation of the display panel. The rows composed of different pixel driving circuits 10 may correspond to their respective multiple signal transmission lines 20, so as to achieve the purpose of performing row-by-row scanning control on the pixel driving circuits 10 in different rows.

To facilitate the electrical connection between components (such as transistors, capacitors, etc.) in the pixel driving circuit 10 and the signal transmission line 20, and to enable the signal transmission line 20 to achieve a better signal transmission effect, the line layout of the pixel driving circuit 10 and the signal transmission line 20 may be optimized. For example, in some embodiments, at the same row of pixel driving circuits 10, at least a portion of the signal transmission line 20 may be set between the driving transistor M0 and the first transistor M1 of the pixel driving circuit 10, so as to facilitate the electrical connection between the components at both sides of the signal transmission line 20 and the signal transmission line 20, thereby ensuring that the signal transmission effect of the signal transmission line 20 to the pixel driving circuit 10 is high, improving the performance of the display panel, and improving the display effect of the display panel.

In some embodiments, the display panel provided in the present disclosure may be a display panel including a frame area, that is, the display panel may include a display area and a non-display area at least partially surrounding the display area. At least the display area may be provided with a pixel driving circuit 10 and a light-emitting element 30, and at least the non-display area may be provided with a corresponding driving circuit for providing a control signal and a signal line for providing an input signal. The non-display area of some display panels may also be provided with a portion of the light-emitting element 30 and/or a portion of the pixel driving circuit 10, and the display area of some display panels may also be provided with a partial structure of the driving circuit and/or a partial structure of the signal line, which all belong to the display panel applicable to the present disclosure.

In some other embodiments, the display panel provided in the present disclosure may also be a frameless display panel. The pixel driving circuit 10, the light-emitting element 30, at least a portion of the structure of the driving circuit, and at least a portion of the structure of the signal line of the frameless display panel may all be provided in the display area. The display panel provided in the present disclosure may be the display panel with frame or the frameless display panel as described above, or may also be other types of display panels, without specific restrictions.

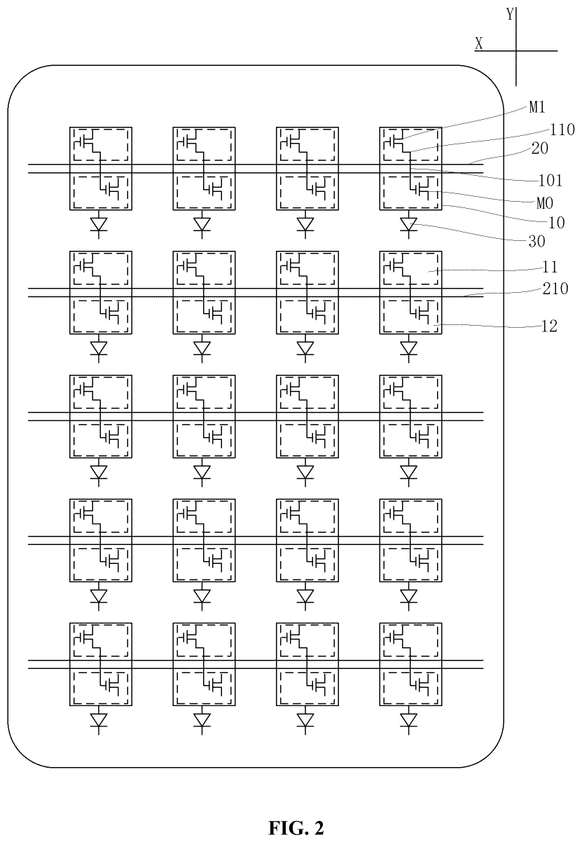

As shown in FIG. 2, the pixel driving circuit 10 may include a first partial circuit 11 and a second partial circuit 12 arranged relatively to each other in the second direction Y. The plurality of signal transmission lines 20 may include at least two first intermediate signal transmission lines 210 located between the first partial circuit 11 and the second partial circuit 12. The first transistor M1 may be located in the first partial circuit 11, the driving transistor M0 may be located in the second partial circuit 12, and the first connection line portion 101 of the gate device connection line 110 may at least partially overlap with the at least two first intermediate signal transmission lines 210 (here, the at least two first intermediate signal transmission lines 210 may be the whole of all the first intermediate signal transmission lines 210). It can be seen that, compared with the situation where the connection lines between the components in the second partial circuit 12 and the signal transmission lines 20 need to be lengthened when all the signal transmission lines 20 are arranged on the side of the first circuit 11 away from the second circuit 12, and compared with the situation where the connection lines between the components in the first circuit 11 and the signal transmission lines 20 need to be lengthened when all the signal transmission lines 20 are arranged on the side of the second circuit 12 away from the first circuit 11, the present disclosure may arrange the first intermediate signal transmission line 210 between the first partial circuit 11 and the second partial circuit 12, which may shorten the length of the connection line between the components in the two circuits and the first intermediate signal transmission line 210. Shortening the length of the connection line may not only achieve the purpose of shortening the signal transmission path, but also shortening the length of the connection line may mean that the coupling interference from other signal lines may be reduced, which may greatly improve the effect of signal transmission to the pixel driving circuit 10 and improve the performance of the display panel.

In one embodiment, all the first intermediate signal transmission lines 210 may be arranged along the second direction Y. The first intermediate signal transmission lines 210 electrically connected to the components in the first partial circuit 11 may be arranged at the side adjacent to the first partial circuit 11, and the first intermediate signal transmission lines 210 electrically connected to the components in the second partial circuit 12 may be arranged on the side adjacent to the second partial circuit 12, and there may be no restriction on the position of the first intermediate signal transmission lines 210 electrically connected to the components in the first partial circuit 11 and the components in the second partial circuit 12. For example, the first intermediate signal transmission lines 210 electrically connected to the components in the first partial circuit 11 and the components in the second partial circuit 12 may be arranged in the middle position of the arrangement sequence of all the first intermediate signal transmission lines 210, which may further reduce the length of the connection line between the components in the two circuits and the first intermediate signal transmission lines 210, thereby further improving the performance of the display panel.

In some embodiments, the components in the first partial circuit 11 and the second partial circuit 12 may be arranged in the second direction Y, and then a portion of the signal transmission line 20 may be set between one or some components and the first intermediate signal transmission line 210, which may not only facilitate the connection between the component and the signal transmission line 20, but also allow the partial structure of the component to multiplex a portion of the line segment in the signal transmission line 20, thereby reducing the number of film layers prepared and reducing the preparation cost of the display panel.

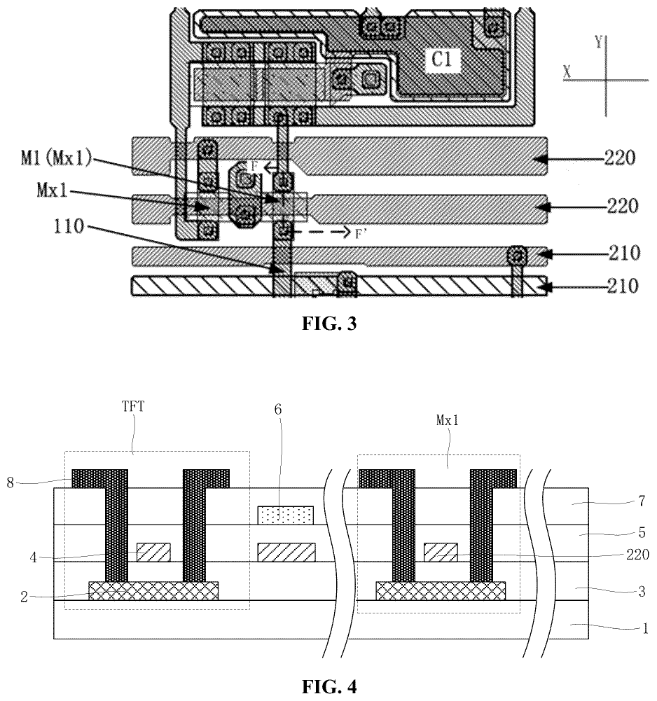

FIG. 3 is a partial circuit layout of the pixel driving circuit 10. As shown in FIG. 3, the first partial circuit 11 may include a first capacitor C1, and the plurality of signal transmission lines 20 may also include at least one second intermediate signal transmission line 220 located between at least two first intermediate signal transmission lines 210 (here, at least two first intermediate signal transmission lines 210 may be the whole of all first intermediate signal transmission lines 210) and the first capacitor C1, and the second intermediate signal transmission line 220 may extend in the first direction X. The orthographic projection of at least one transistor Mx1 in the first partial circuit 11 on the substrate may at least partially overlap with the orthographic projection of the second intermediate signal transmission line 220 on the substrate.

In some embodiments, the transistor Mx1 may include a first transistor M1, that is, the first transistor M1 may be located between the first capacitor C1 and the first intermediate signal transmission line 210. Further, the orthographic projections of the transistor Mx1 and the second intermediate signal transmission line 220 on the substrate may at least partially overlap, and a portion of the second intermediate signal transmission line 220 may be multiplexed as the gate of the transistor Mx1.

FIG. 4 illustrates at least an FF′-sectional view in FIG. 3. As shown in FIG. 4, the display panel may include a substrate 1, and a semiconductor layer 2 located on the substrate 1. The semiconductor layer 2 may include an active area for preparing a transistor TFT. The display panel may also include a gate insulation layer 3 located on the side of the semiconductor layer 2 away from the substrate 1; and a gate metal layer 4 located on the side of the gate insulation layer 3 away from the substrate 1. The gate metal layer 4 may include a gate for preparing a transistor TFT. Further, the display panel may include an interlayer insulation layer 5 located on the side of the gate metal layer 4 away from the substrate 1; and a capacitor metal layer 6 located on the side of the interlayer insulation layer 5 away from the substrate 1. The capacitor metal layer 6 may be provided with a plate for forming a capacitor, and the other plate of the capacitor may be located at the gate metal layer 4 or the source-drain metal layer 8. Further, the display panel may include an insulation dielectric layer 7 located on the side of the capacitor metal layer 6 away from the substrate 1; and a source-drain metal layer 8 located on the side of the insulation dielectric layer 7 away from the substrate 1. The source-drain metal layer 8 may include a source and a drain for preparing a transistor TFT. Among them, the gate of the transistor Mx1 may multiplex a part of the line segment of the second intermediate signal transmission line 220. It should be noted that the present disclosure does not impose any specific restrictions on the use of the transistor Mx1 to multiplex the portion of the second intermediate signal transmission line 220. For example, in other embodiments, the transistor Mx1 may also multiplex a portion of the second intermediate signal transmission line 220 as a source or drain, which may need to be specifically designed according to the multiplexing requirements of the transistor Mx1, the film layer where the second intermediate signal transmission line 220 is located, and other parameters.

FIG. 3 shows an embodiment in which at least one signal transmission line 20 passes through the first partial circuit 11. Similarly, at least one signal transmission line 20 may also pass through the second partial circuit 12. FIG. 5 illustrates a partial circuit layout of the pixel driving circuit 10. As shown in FIG. 5, the second partial circuit 12 may include a second capacitor C2, and the plurality of signal transmission lines 20 may also include at least one third intermediate signal transmission line 230 located between at least two first intermediate signal transmission lines 210 (here, the at least two first intermediate signal transmission lines 210 may be the whole of all the first intermediate signal transmission lines 210) and the second capacitor C2, and the third intermediate signal transmission line 230 may extend in the first direction X. The orthographic projection of at least one transistor Mx2 in the second partial circuit 12 on the substrate may at least partially overlap with the orthographic projection of the third intermediate signal transmission line 230 on the substrate.

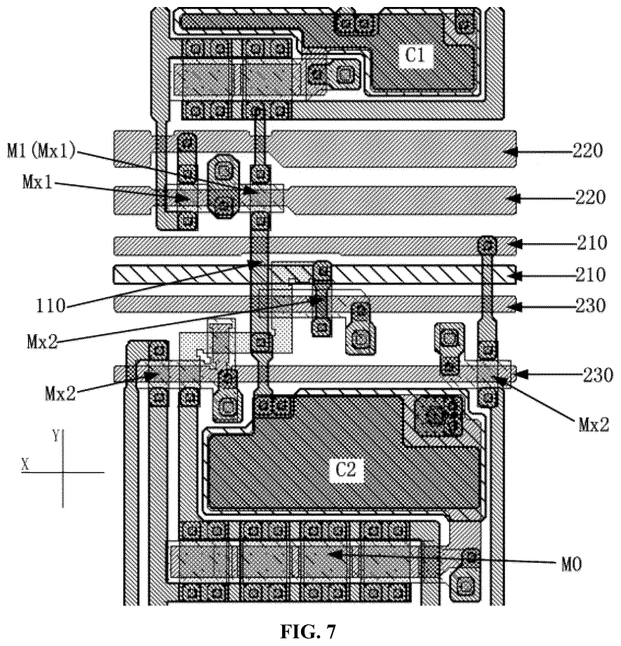

In some embodiments, the driving transistor M0 may be located between the second capacitor C2 and the first intermediate signal transmission line 210, and the third intermediate signal transmission line 230 may be located between the driving transistor M0 and the first intermediate signal transmission line 210 (as shown in FIG. 5, the driving transistor M0 may be located between the second capacitor C2 and the first intermediate signal transmission line 210); or, the driving transistor M0 may also be located on the side of the second capacitor C2 away from the first intermediate signal transmission line 210 (as shown in FIG. 7, the driving transistor M0 may be located on the side of the second capacitor C2 away from the first intermediate signal transmission line 210), which may need to be specifically designed according to the actual application.

In some embodiments, the orthographic projections of the transistor Mx2 and the third intermediate signal transmission line 230 on the substrate may at least partially overlap, and a portion of the line segment of the third intermediate signal transmission line 230 may be multiplexed as the gate of the transistor Mx2.

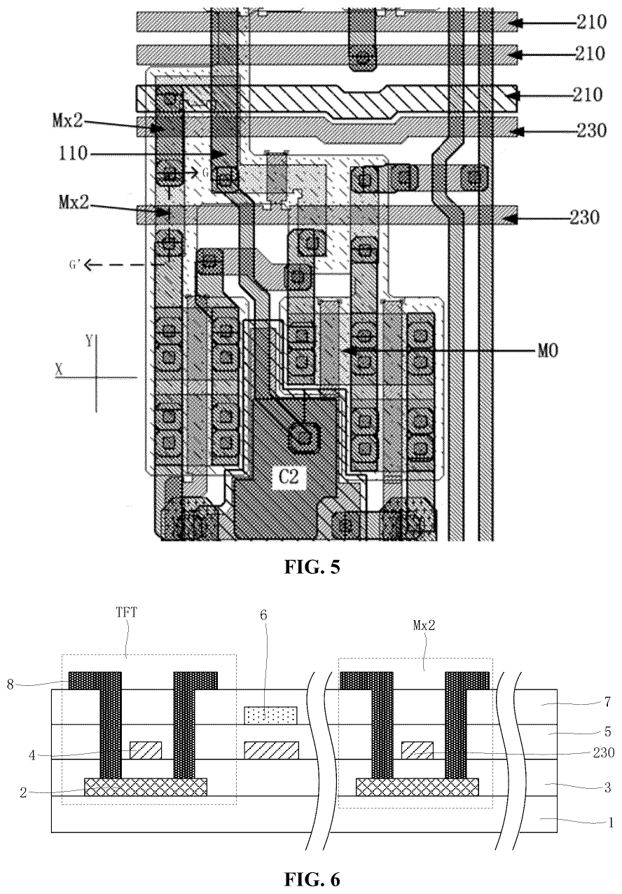

FIG. 6 illustrates at least a GG′-sectional view in FIG. 5. As shown in FIG. 6, the display panel may include a substrate 1 and a semiconductor layer 2 located on the substrate 1. The semiconductor layer 2 may include an active area for preparing a transistor TFT. The display panel may also include a gate insulation layer 3 located on the side of the semiconductor layer 2 away from the substrate 1; and a gate metal layer 4 located on the side of the gate insulation layer 3 away from the substrate 1. The gate metal layer 4 may include a gate for preparing the transistor TFT. Further, the display panel may include an interlayer insulation layer 5 located on the side of the gate metal layer 4 away from the substrate 1; and a capacitor metal layer 6 located on the side of the interlayer insulation layer 5 away from the substrate 1. The capacitor metal layer 6 may be provided with a plate for forming a capacitor, and the other plate of the capacitor may be located at the gate metal layer 4 or the source-drain metal layer 8. Further, the display panel may include an insulation dielectric layer 7 located on the side of the capacitor metal layer 6 away from the substrate 1; and a source-drain metal layer 8 located on the side of the insulation dielectric layer 7 away from the substrate 1. The source-drain metal layer 8 may include a source and a drain for preparing a transistor TFT. Among them, the gate of the transistor Mx2 may multiplex a part of the line segment of the second intermediate signal transmission line 220. It should be noted that the present disclosure does not impose any specific restrictions on the use of the transistor Mx2 to multiplex a portion of the third intermediate signal transmission line 230. For example, in some other embodiments, the transistor Mx2 may also multiplex a portion of the third intermediate signal transmission line 230 as a source or drain, which may need to be specifically designed according to the multiplexing requirements of the transistor Mx2, the film layer where the third intermediate signal transmission line 230 is located, and other parameters.

In addition, FIG. 7 also shows an embodiment in which at least one signal transmission line 20 passes through both the first partial circuit 11 and the second partial circuit 12. As shown in FIG. 7, the first partial circuit 11 may include a first capacitor C1, and the plurality of signal transmission lines 20 may also include at least one second intermediate signal located between at least two first intermediate signal transmission lines 210 (here, the at least two first intermediate signal transmission lines 210 may be the entirety of all first intermediate signal transmission lines 210) and the first capacitor C1. The second intermediate signal transmission line 220 may extend along the first direction X. The orthographic projection of at least one transistor Mx1 in the first partial circuit 11 on the substrate may overlap at least partially with the orthographic projection of the second intermediate signal transmission line 220 on the substrate. At the same time, the second partial circuit 12 may include a second capacitor C2, and the plurality of signal transmission lines 20 may also include at least one third intermediate signal transmission line 230 located between at least two first intermediate signal transmission lines 210 (here, at least two first intermediate signal transmission lines 210 may be the whole of all first intermediate signal transmission lines 210) and the second capacitor C2, and the third intermediate signal transmission line 230 may extend along the first direction X. The orthographic projection of at least one transistor Mx2 in the second partial circuit 12 on the substrate may overlap at least partially with the orthographic projection of the third intermediate signal transmission line 230 on the substrate. By setting the second intermediate signal transmission line 220 and the third intermediate signal transmission line 230, the connection between the component and the signal transmission line 20 may be more convenient, and at the same time, the electrodes of some transistors may multiplex some line segments in the signal transmission line 20, thereby reducing the number of film layers prepared and reducing the preparation cost of the display panel.

As shown in FIG. 3 to FIG. 7, at the overlapping area of the transistor Mx1 and the second intermediate signal transmission line 220 in the first partial circuit 11, and/or at the overlapping area of the transistor Mx2 and the third intermediate signal transmission line 230 in the second partial circuit 12, the gate of the transistor may multiplex a portion of the line segment of the corresponding intermediate signal transmission line. That is, at the overlapping area of the orthographic projections of the transistor Mx1 and the second intermediate signal transmission line 220 on the substrate, the gate of the transistor Mx1 may multiplex a portion of the line segment of the second intermediate signal transmission line 220; and at the overlapping area of the orthographic projections of the transistor Mx2 and the third intermediate signal transmission line 230 on the substrate, the gate of the transistor Mx2 may multiplex a portion of the line segment of the third intermediate signal transmission line 230. In other embodiments, the transistor may also multiplex a portion of the line segment of the corresponding intermediate signal transmission line as the source or drain, which may need to be specifically designed according to the multiplexing requirements of the transistor, the film layer where the intermediate signal transmission line is located, and other parameters.

It can be understood that the above content describes the relevant technical solutions in which the signal transmission line 20 may be located in the middle position of the pixel driving circuit 10, which may at least achieve the effect of facilitating the electrical connection between the components in the pixel driving circuit 10 and the middle signal transmission line. Furthermore, a portion of the signal transmission line 20 may be set at least one side edge of the pixel driving circuit 10 in the second direction Y, which may make the connection between the components located at the edge of the pixel driving circuit 10 and the signal transmission line 20 more convenient, shortening more signal transmission paths.

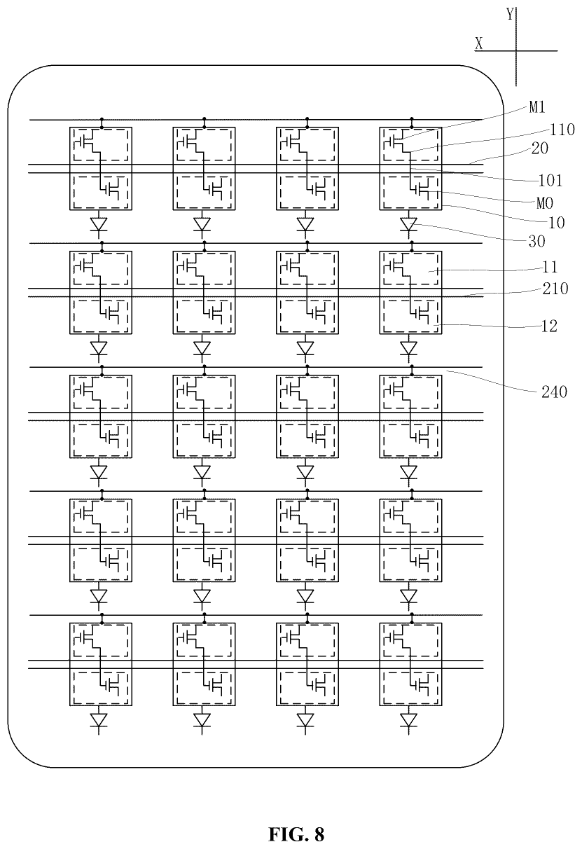

As shown in FIG. 8, in one embodiment, for the pixel driving circuits 10 in the same row, the multiple signal transmission lines 20 may also include at least one first edge signal transmission line 240 located on the side of the first partial circuit 11 away from the second partial circuit 12, so that the components connected to the first edge signal transmission line 240 may be set at the edge of the first partial circuit 11, shortening the connection line between the first edge signal transmission line 240 and the corresponding component, thereby reducing the risk of the corresponding connection line being interfered by coupling with other signal lines.

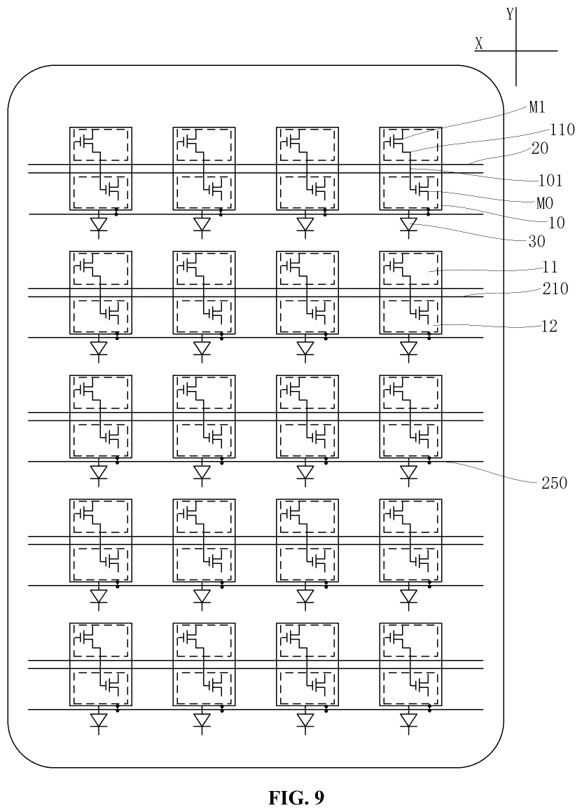

As shown in FIG. 9, in one embodiment, for the pixel driving circuits 10 in the same row, the plurality of signal transmission lines 20 may also include at least one second edge signal transmission line 250 located at the side of the second partial circuit 12 away from the first partial circuit 11. Therefore, a component connected to the second edge signal transmission line 250 may be arranged at the edge of the second partial circuit 12, shortening the connection line between the second edge signal transmission line 250 and the corresponding component, thereby reducing the risk of the corresponding connection line being interfered by coupling with other signal lines.

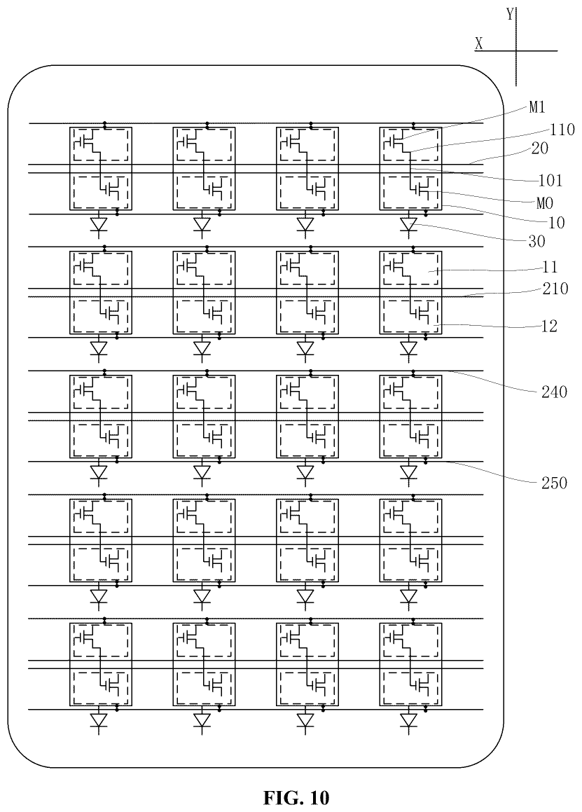

In another embodiment, as shown in FIG. 10, for the pixel driving circuits 10 in the same row, the plurality of signal transmission lines 20 may also include at least one first edge signal transmission line 240 located at the side of the first partial circuit 11 away from the second partial circuit 12. At the same time, the plurality of signal transmission lines 20 may also include at least one second edge signal transmission line 250 located at the side of the second partial circuit 12 away from the first partial circuit 11, thereby a component connected to the first edge signal transmission line 240 may be arranged at the edge of the first partial circuit 11, and a component connected to the second edge signal transmission line 250 may be arranged at the edge of the second partial circuit 12, thereby shortening the connection line between the edge signal transmission line and the corresponding component, thereby reducing the risk of the corresponding connection line being interfered by coupling with other signal lines.

In some embodiments, the components in the first circuit 11 and the second circuit 12 may be arranged along the second direction Y, and then a portion of the signal transmission line 20 may be set between one or some components and the edge signal transmission line, which may not only makes it easier to connect the component with the signal transmission line 20, but also allow the portion of the structure of the component to multiplex a portion of the line segment in the signal transmission line 20, thereby reducing the number of film layers and the preparation cost of the display panel.

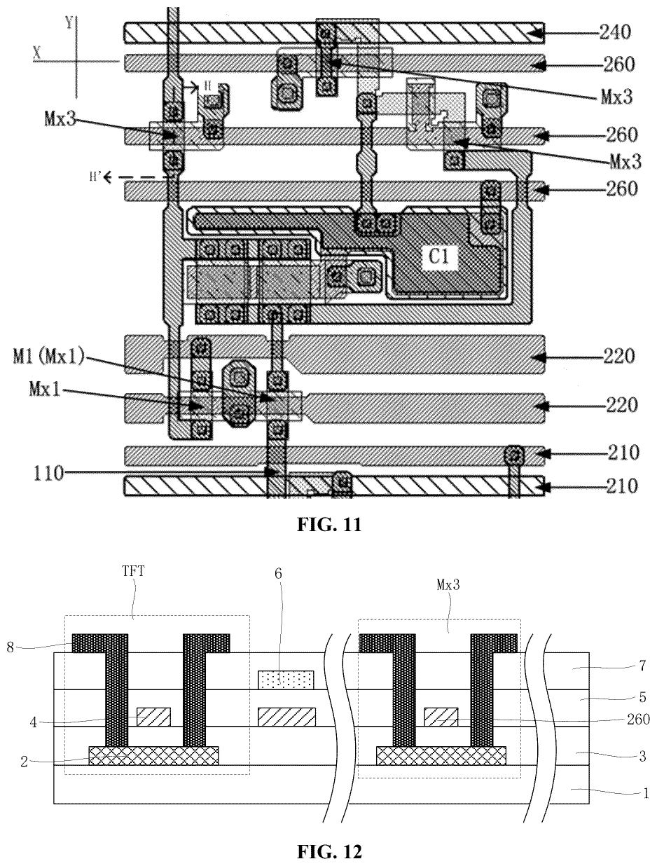

As shown in FIG. 11, the first partial circuit 11 may include a first capacitor C1, and the plurality of signal transmission lines 20 may also include a third edge signal transmission line 260 located between at least one first edge signal transmission line 240 (here, at least one first edge signal transmission line 240 may be the whole of all first edge signal transmission lines 240) and the first capacitor C1; and the orthographic projection of at least one transistor Mx3 in the first circuit 11 on the substrate may overlap at least partially with the orthographic projection of the third edge signal transmission line 260 on the substrate.

In some embodiments, the orthographic projections of the transistor Mx3 and the third edge signal transmission line 260 on the substrate may at least partially overlap, and a portion of the line segment of the third edge signal transmission line 260 may be multiplexed for the gate of the transistor Mx3. FIG. 12 is a cross-sectional view at least along HH′ in FIG. 11. As shown in FIG. 12, the display panel may include a substrate 1 and a semiconductor layer 2 located on the substrate 1. The semiconductor layer 2 may include an active area for preparing a transistor TFT. The display panel may also include a gate insulation layer 3 located on the side of the semiconductor layer 2 away from the substrate 1; and a gate metal layer 4 located on the side of the gate insulation layer 3 away from the substrate 1. The gate metal layer 4 may include a gate for preparing a transistor TFT. Further, the display panel may include an interlayer insulation layer 5 located on the side of the gate metal layer 4 away from the substrate 1; and a capacitor metal layer 6 located on the side of the interlayer insulation layer 5 away from the substrate 1. The capacitor metal layer 6 may be provided with a plate for forming a capacitor, and the other plate of the capacitor may be located at the gate metal layer 4 or the source-drain metal layer 8. Further, the display panel may include an insulation dielectric layer 7 located on the side of the capacitor metal layer 6 away from the substrate 1; and a source-drain metal layer 8 located on the side of the insulation dielectric layer 7 away from the substrate 1. The source-drain metal layer 8 may include a source and a drain for preparing a transistor TFT. Among them, the gate of the transistor Mx3 may multiplex a portion of the line segment of the second intermediate signal transmission line 220. It should be noted that the present application does not impose any specific restrictions on the use of the transistor Mx3 to multiplex a portion of the third edge signal transmission line 260. For example, in some other embodiments, the transistor Mx3 may also multiplex a portion of the third edge signal transmission line 260 as a source or drain, which may need to be specifically designed according to the multiplexing requirements of the transistor Mx3, the film layer where the third edge signal transmission line 260 is located, and other parameters.

FIG. 11 shows that at least one edge signal transmission line passes through the first partial circuit 11. Similarly, at least one edge signal transmission line may also pass through the second partial circuit 12; that is, the second partial circuit 12 may include a second capacitor C2, and the plurality of signal transmission lines 20 may also include a fourth edge signal transmission line located between at least one second edge signal transmission line 250 (here, at least one second edge signal transmission line 250 may be the whole of all second edge signal transmission lines 250) and the second capacitor C2. The orthographic projection of at least one transistor in the second partial circuit 12 on the substrate may overlap at least partially with the orthographic projection of the fourth edge signal transmission line on the substrate. Among them, the orthographic projections of the transistor and the fourth edge signal transmission line on the substrate may at least partially overlap, and a portion of the fourth edge signal transmission line may be multiplexed as the gate of the transistor. It should be noted that the present disclosure does not specifically limit the use of the transistor multiplexing a portion of the fourth edge signal transmission line. For example, in other embodiments, the transistor may also multiplexing a portion of the fourth edge signal transmission line as a source or drain, which may need to be specifically designed according to the multiplexing requirements of the transistor, the film layer where the fourth edge signal transmission line is located, and other parameters.

In addition, at least one edge signal transmission line may be set through the first partial circuit 11 and the second partial circuit 12 provided in the embodiment of the present disclosure. That is, the first partial circuit 11 may include a first capacitor C1, and the plurality of signal transmission lines 20 may also include a third edge signal transmission line 260 located between at least one first edge signal transmission line 240 (here, at least one first edge signal transmission line 240 may be the whole of all first edge signal transmission lines 240) and the first capacitor C1. The orthographic projection of at least one transistor Mx3 in the first partial circuit 11 on the substrate may overlap at least partially with the orthographic projection of the third edge signal transmission line 260 on the substrate. At the same time, the second partial circuit 12 may include a second capacitor C2, and the plurality of signal transmission lines 20 may also include a fourth edge signal transmission line located between at least one second edge signal transmission line 250 (here, at least one second edge signal transmission line 250 may be the whole of all second edge signal transmission lines 250) and the second capacitor C2. The orthographic projection of at least one transistor in the second partial circuit 12 on the substrate may overlap at least partially with the orthographic projection of the fourth edge signal transmission line on the substrate. By setting the third edge signal transmission line 260 and the fourth edge signal transmission line, the connection between the component and the signal transmission line 20 may be more convenient, and at the same time, the electrodes of some transistors may multiplex some line segments in the signal transmission line 20, thereby reducing the number of film layers prepared and reducing the preparation cost of the display panel.

Combined with FIGS. 9-12, in the overlapping area of the transistor Mx3 and the third edge signal transmission line 260 in the first partial circuit 11, and/or, in the overlapping area of the transistor and the fourth edge signal line in the second partial circuit 12, the gate of the transistor may multiplex some line segments of the corresponding edge signal transmission line. That is, at the overlapping area of the positive projection of the transistor Mx3 and the third edge signal transmission line 260 on the substrate, a portion of the line segment of the third edge signal transmission line 260 may be multiplexed as the gate of the transistor Mx3; and at the overlapping area of the orthographic projections of the transistor and the fourth edge signal transmission line on the substrate, a portion of the line segment of the fourth edge signal transmission line may be multiplexed as the gate of the transistor. In other embodiments, the transistor may also multiplex a portion of the line segment of the corresponding edge signal transmission line as the source or drain, which may need to be specifically designed according to the multiplexing requirements of the transistor, the film layer where the edge signal transmission line is located, and other parameters.

In some embodiments, the display panel may include only any one of the second intermediate signal transmission line 220, the third intermediate signal transmission line 230, the first edge signal transmission line 240, and the second edge signal transmission line 250 on the basis of including the first intermediate signal transmission line 210. When the display panel includes the first edge signal transmission line 240, the display panel may further include the third edge signal line 260; and when the display panel includes the second edge signal line 250, the display panel may further include the fourth edge signal line. In other embodiments, the display panel may include a combination of at least two of the second intermediate signal transmission line 220, the third intermediate signal transmission line 230, the first edge signal transmission line 240, and the second edge signal transmission line 250 on the basis of including the first intermediate signal transmission line 210. When the display panel includes the first edge signal transmission line 240, the display panel may further include the third edge signal line 260; and when the display panel includes the second edge signal line 250, the display panel may further include the fourth edge signal line. Further, when the display panel includes any one of the second intermediate signal transmission line 220, the third intermediate signal transmission line 230, the third edge signal transmission line 260 and the fourth edge signal transmission line, the transistor Mx1 in the display panel may multiplex a portion of the line segment of the second intermediate signal transmission line 220, the transistor Mx2 may multiplex a portion of the line segment of the third intermediate signal transmission line 230, the transistor Mx3 may multiplex a portion of the line segment of the third edge signal transmission line 260, and the transistor Mx4 may multiplex a portion of the line segment of the fourth edge signal transmission line.

In the pixel driving circuit 10, it may be necessary to realize the connection between components through the device connection line 100, and realize the connection between components and the signal transmission line 20, for example, the gate device connection line 110 may connect one terminal of the first transistor M1 to the gate of the driving transistor M0, thereby realizing the connection between components in the pixel driving circuit 10. Because the first partial circuit 11 and the second partial circuit 12 may be arranged along the second direction Y, and the arrangement of some components in the pixel driving circuit 10 may be also arranged along the second direction Y, at least a portion of the device connection line 100 may inevitably overlap with the signal transmission line 20, and the overlapping line may be optimized to reduce the coupling interference problem.

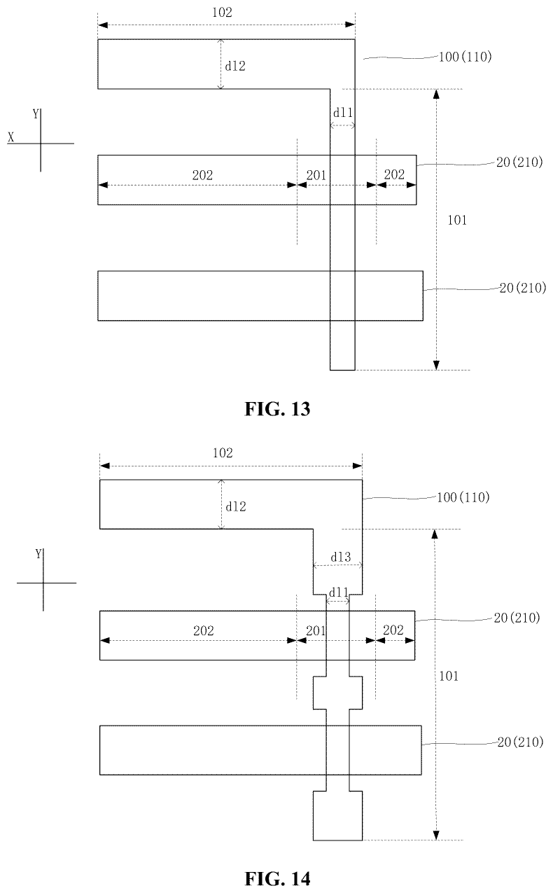

As shown in FIG. 13, taking the gate device connection line 110 as an example, and FIG. 13 is a schematic diagram of the overlapping area of the gate device connection line 110 and the first intermediate signal transmission line 210, the pixel driving circuit 10 may include a plurality of device connection lines 100, and the plurality of device connection lines 100 may include the gate device connection line 110. At least one device connection line 100 may include at least a first connection line portion 101 extending in the second direction Y, and the at least one device connection line 100 may also include a second connection line portion 102. The second connection line portion 102 may extend along the second direction Y, or the second connection line portion 102 may extend along the first direction X, or the second connection line portion 102 may extend along any direction at the angle between the first direction X and the second direction Y. At least one signal transmission line 20 (such as the first intermediate signal transmission line 210 shown in FIG. 13) may include a first transmission line portion 201 and a second transmission line portion 202. In the direction perpendicular to the plane where the display panel is located, at least one first connection line portion 101 may overlap with at least one first transmission line portion 201, and the first connection line portion 101 of the gate device connection line 110 may overlap with at least two first transmission line portions 201. At least in the overlapping area between the first connection line portion 101 and the first transmission line portion 201, the line width dl1 of the first connection line portion 101 may be smaller than the line width dl2 of the second connection line portion 201. Thus, by reducing the line width of the first connection line portion 101 at the overlapping area with the first transmission line portion 201, the overlapping area of the first connection line portion 101 and the first transmission line portion 201 may be reduced, thereby reducing the coupling interference problem at the overlapping area of the device connection line 100 and the signal transmission line 20, improving the signal transmission effect of the line, and ensuring the high performance of the display panel.

It can be understood that the line width dl1 of the first connection line portion 101 provided in the embodiment of the present disclosure may be smaller than the line width dl2 of the second connection line portion 201, at least in the overlapping area of the first connection line portion 101 and the first transmission line portion 201; that is, the overall line width of the first connection line portion 101 may be uniformly dl1, and the line width at any point of the first connection line portion 101 may be smaller than the line width dl2 of the second connection line portion 201, reference can be made to the first connection line portion 101 with uniform overall line width shown in FIG. 13.

In another embodiment, as shown in FIG. 14, the overall line width of the first connection portion 101 may be a non-uniform line width, and the line width of the first connection line portion 101 may be dl1 only at the overlapping area between the first connection line portion 101 and the first transmission line portion 201, while the line width of the rest of the first connection line portion 101 may be set to be dl3, such as the line width of the first connection line portion 101 between the two first intermediate signal transmission lines 210, etc., dl3 may be greater than dl1, and dl3 may be less than dl2, equal to dl2 or greater than dl2. In one embodiment, the line width of dl3 is equal to or greater than dl2, and on the basis of being able to reduce the coupling interference problem at the overlapping area of the device connection line 100 and the signal transmission line 20, the overall impedance of the device connection line 100 may be ensured to be small, and the signal transmission capability of the device connection line 100 may be improved.

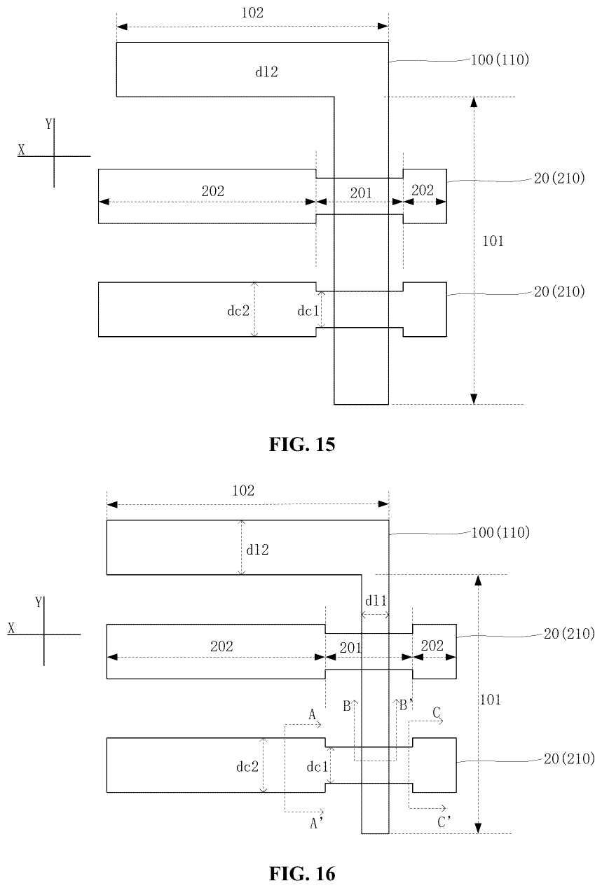

FIGS. 13-14 show that the coupling interference at the overlapping area of the device connection line 100 and the signal transmission line 20 may be reduced by optimizing the line width of the first connection line portion 101. Similarly, the coupling interference at the overlapping area between the device connection line 100 and the signal transmission line 20 may also be reduced by optimizing the line width of the signal transmission line 20. Specifically, as shown in FIG. 15, the gate device connection line 110 is taken as an example for explanation, and FIG. 13 is a schematic diagram of the overlapping area between the gate device connection line 110 and the first intermediate signal transmission line 210. As shown in FIG. 13 and FIG. 15, the pixel driving circuit 10 may include a plurality of device connection lines 100, and the plurality of device connection lines 100 may include the gate device connection line 110. At least one device connection line 100 may include at least a first connection line portion 101 extending along the second direction Y, and the at least one device connection line 100 may also include a second connection line portion 102. The second connection line portion 102 may extend along the second direction Y, or the second connection line portion 102 may extend along the first direction X, or the second connection line portion 102 may extend along any direction at the angle between the first direction X and the second direction Y. At least one signal transmission line 20 (such as the first intermediate signal transmission line 210 shown in FIG. 13) may include a first transmission line portion 201 and a second transmission line portion 202. In a direction perpendicular to the plane where the display panel is located, at least one first connection line portion 101 may overlap with at least one first transmission line portion 201, and the first connection line portion 101 of the gate device connection line 110 may overlap with at least two first transmission line portions 201. At least in the overlapping area between the first connection line portion 101 and the first transmission line portion 201, the line width dc1 of the first transmission line portion 201 may be smaller than the line width dc2 of the second transmission line portion 202. Thus, by reducing the line width of the first transmission line portion 201 at the overlapping area with the first connection line portion 101, the overlapping area between the first connection line portion 101 and the first transmission line portion 201 may be reduced, thereby reducing the coupling interference problem at the overlapping area between the device connection line 100 and the signal transmission line 20, improving the signal transmission effect of the line, and ensuring the high performance of the display panel.

The line width of the first connection line portion 101 of the device connection line 100 may be optimized separately, and the line width of the first transmission line portion 201 of the signal transmission line 20 may also be optimized separately, so as to reduce the coupling interference problem at the overlapping area of the device connection line 100 and the signal transmission line 20. In addition, the line widths of the first connection line portion 101 of the device connection line 100 and the first transmission line portion 201 of the signal transmission line 20 may be optimized at the same time, which may further reduce the coupling interference problem at the overlapping area of the device connection line 100 and the signal transmission line 20.

FIG. 16 is a schematic diagram of a signal transmission line 20 based on FIG. 13. As shown in FIG. 16, at least in the overlapping area between the first connection line portion 101 and the first transmission line portion 201, the line width dl1 of the first connection line portion 101 may be smaller than the line width dl2 of the second connection line portion 201, and the line width dc1 of the first transmission line portion 201 may be smaller than the line width dc2 of the second transmission line portion 202. The first connection line portion 101 with a line width dl1 and the first transmission line portion 201 with a line width dc1 may overlap, further reducing the overlapping area between the first connection line portion 101 and the first transmission line portion 201, and further reducing the coupling interference problem at the overlapping area between the device connection line 100 and the signal transmission line 20.

In some embodiments, the signal transmission line 20 illustrated in FIG. 15 may also be applied to the embodiment illustrated in FIG. 14, and no unnecessary elaboration may be made in this disclosure. In the embodiments of the present disclosure, the line widths dl1, dl2, dl3, dc1 and dc2 may not be limited in their specific numerical ranges. Similarly, the size relationship between the line widths dl1, dl2 and dl3 of the device connection line 100 and the line widths dc1 and dc2 of the signal transmission line 20 may not be limited, and it may need to be specifically designed and selected according to the actual application.

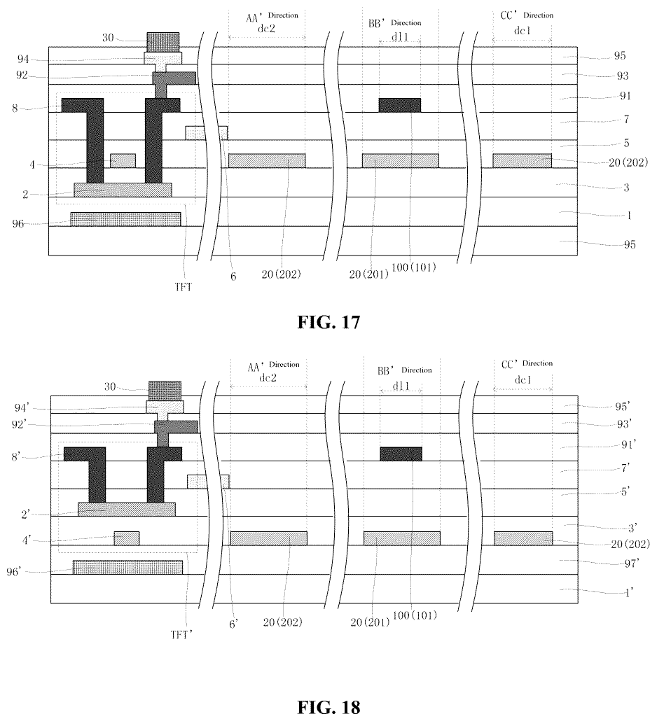

The corresponding embodiments of FIGS. 13-16 above are schematically described for the line widths of the device connection line 100 and the signal transmission line 20 in the direction parallel to the plane where the display panel is located. The line width is schematically described in the section direction perpendicular to the plane where the display panel is located with reference to FIG. 17 below. FIG. 17 is an AA′, BB′ and CC′-sectional view in FIG. 16. The display panel may include a substrate 1 and a semiconductor layer 2 located on the substrate 1. The semiconductor layer 2 may include an active area for preparing a transistor TFT. The display panel may also include a gate insulation layer 3 located on the side of the semiconductor layer 2 facing away from the substrate 1; and a gate metal layer 4 located on the side of the gate insulation layer 3 facing away from the substrate 1. The gate metal layer 4 may include a gate for preparing a transistor TFT. Further, the display panel may include an interlayer insulation layer 5 located on the side of the gate metal layer 4 facing away from the substrate 1; and a capacitor metal layer 6 located on the side of the interlayer insulating layer 5 facing away from the substrate 1. The capacitor metal layer 6 may be provided with a plate for forming a capacitor, and the other plate of the capacitor may be located on the gate metal layer 4 or the source-drain metal layer 8. Further, the display panel may include an insulation dielectric layer 7 located on the side of the capacitor metal layer 6 facing away from the substrate 1; and a source-drain metal layer 8 located on the side of the insulation dielectric layer 7 facing away from the substrate 1. The source-drain metal layer 8 may include a source and a drain for preparing a transistor TFT. In one embodiment, the device connection line 100 may be made of a source-drain metal layer 8, and the signal transmission line 20 overlapping the device connection line 100 may be made of the gate metal layer 4 or the capacitor metal layer 6. The line width dl1 of the first connection line portion 101 may be smaller than the line width dl2 of the second connection line portion 102, and the line width dc1 of the first transmission line portion 201 may be smaller than the line width dc2 of the second transmission line portion 202. It should be noted that the metal layers where different device connection lines 100 are located may be different, and the metal layers where different signal transmission lines 20 are located may be different. For example, the device connection line 110 may be made of the capacitor metal layer 6 and the source-drain metal layer 8, and the signal transmission line 20 may be made of the gate metal layer 3 and the capacitor metal layer 6. In other embodiments, the display panel may also be made of more metal layers, such as a fourth metal layer on the side of the source-drain metal layer 8 away from the substrate 1, etc., for preparing more signal lines, etc., and this disclosure does not make specific restrictions on this.

Further, referring to FIG. 17, the display panel provided by one embodiment of the present disclosure may form a planarization layer 91 on the source/drain metal layer 8 after the source/drain metal layer 8 is formed (in some embodiments, a passivation layer may be provided between the source/drain metal layer 8 and the planarization layer 91); a first power line layer 92 may be formed on the planarization layer 91; and the first power line layer 92 may be formed with a power line for providing a power supply voltage PVDD; and may also be formed with a first via electrode electrically connected to a transistor TFT (for example, the transistor TFT may be a transistor electrically connected to the light-emitting element 30); and then a first via electrode may be formed on the side of the first power line layer 92 facing away from the substrate 1. Then, a power insulation layer 93 may be formed; a second power line layer 94 may be formed on the side of the power insulation layer 93 away from the substrate 1, and the second power line layer 94 may be formed with a power line for providing a cathode voltage PVEE, and a second via electrode electrically connected to the first via electrode may be formed. Finally, a device insulation layer 95 may be formed on the side of the second power line 94 away from the substrate 1. The device insulation layer 95 may include a hollowed out structure of the exposed second via electrode, and the light-emitting element 30 may be arranged at the hollowed out structure to be electrically connected to the second via electrode, and the transistor TFT may be electrically connected to the light-emitting element 30 through the first via electrode and the second via electrode. Further, a light-shielding metal layer 96 may also be included between the substrate 1 and the semiconductor layer 2, and an insulation layer 97 may also be provided between a light-shielding metal layer 96 and the semiconductor layer 2. The light-shielding metal layer 96 may include a light-shielding metal block corresponding to the active area of the transistor TFT, and the light-shielding metal block may not only block the external ambient light on the substrate 1 side from entering the active area, thereby preventing the external ambient light from affecting the performance of the transistor TFT, but also block impurities on the substrate 1 side from entering the active area.

FIG. 17 shows that the transistor TFT of the display panel provided by the embodiment of the present disclosure may be a top-gate transistor. Further, the transistor of the display panel provided by the embodiment of the present disclosure may also be a bottom-gate transistor.

FIG. 18 is another AA′, BB′ and CC′-sectional view in FIG. 16. As shown in FIG. 18, the display panel may include a substrate 1′, and a gate metal layer 4′ located on the substrate 1′. The gate metal layer 4′ may include a gate for preparing a bottom-gate transistor TFT′. The display panel may also include a gate insulation layer 3′ located on the side of the gate metal layer 4′ away from the substrate 1′; and a semiconductor layer 2′ located on the side of the gate insulation layer 3′ away from the substrate 1′. The semiconductor layer 2′ may include an active area for preparing the transistor TFT′. Further, the display panel may include an interlayer insulation layer 5′ located on the side of the semiconductor layer 2′ away from the substrate 1′; and a capacitor metal layer 6′ located on the side of the interlayer insulation layer 5′ away from the substrate 1′. The capacitor metal layer 6′ may be provided with a plate for forming a capacitor, and the other plate of the capacitor may be located on the gate metal layer 4′ or the source-drain metal layer 8′. Further, the display panel may include an insulation dielectric layer 7′ located on the side of the capacitor metal layer 6′ away from the substrate 1; and a source-drain metal layer 8′ located on the side of the insulation dielectric layer 7′ away from the substrate 1′. The source-drain metal layer 8′ may include a source and a drain for preparing the transistor TFT′.

Further, referring to FIG. 18, the display panel provided in the embodiment of the present disclosure may form a planarization layer 91′ on the source-drain metal layer 8′ after forming the source-drain metal layer 8′ (in some embodiments, a passivation layer may be provided between the source-drain metal layer 8′ and the planarization layer 91′). A first power line layer 92′ may be formed on the planarization layer 91′, and the first power line layer 92′ may be formed with a power line for providing a power supply voltage PVDD, and also formed with a first via electrode electrically connected to the transistor TFT′ (for example, the transistor TFT′ may be a transistor electrically connected to the light-emitting element 30). Then, a power insulation layer 93′ may be formed on the side of the first power line layer 92′ away from the substrate 1′; and a second power line layer 94′ may be formed on the side of the power insulation layer 93′ away from the substrate 1. The second power line layer 94′ may be formed with a power line for providing a cathode voltage PVEE. Then, a second via electrode electrically connected to the first via electrode may be formed; and finally, a device insulation layer 95′ may be formed on the side of the second power line 94′ away from the substrate 1′. The device insulation layer 95′ may include a hollowed-out structure exposing the second via electrode, and a light-emitting element 30 may be arranged at the hollowed-out structure to be electrically connected to the second via electrode, and the transistor TFT′ may be electrically connected to the light-emitting element 30 through the first via electrode and the second via electrode. Furthermore, a light-shielding metal layer 96′ may be provided between the substrate 1′ and the semiconductor layer 2′, and an insulation layer 97′ may be further provided between the light-shielding metal layer 96′ and the semiconductor layer 2′. The light-shielding metal layer 96′ may include a light-shielding metal block corresponding to the active area of the transistor TFT, and the light-shielding metal block may not only block the external ambient light on the substrate 1 side from entering the active area, thereby preventing the external ambient light from affecting the performance of the transistor TFT′, but also block the impurities on the substrate 1′ side from entering the active area.

At the overlapping area of the first connection line portion 101 and the first transmission line portion 201, narrowing the line width of at least one of the first connection line portion 101 and the first transmission line portion 201 may reduce the coupling interference problem at the overlapping area of the connection line 100 and the signal transmission line 20. On this basis, the device connection line 100 may be further optimized.

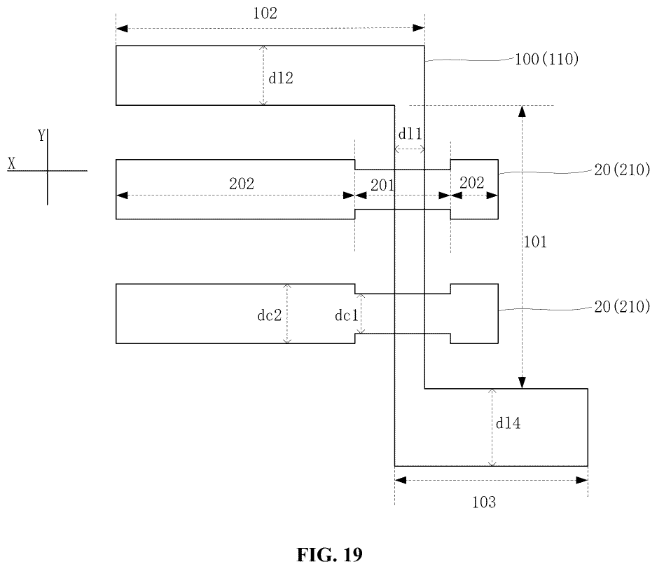

As shown in FIG. 19, in some embodiments, when the line width d11 of the first connection line portion 101 at the overlapping area with the first transmission line portion 201 is smaller than the line width d12 of the second connection line portion 102, the device connection line 100 may further include a third connection line portion 103, and the line width d14 of the third connection line portion 103 may be greater than the line width d12 of the second connection line portion 102. The third connection line portion 103 may be a portion other than the first connection line portion 101, and the third connection line portion 103 shown in FIG. 19 may be a line portion extending along the first direction X (the structure may be only one of all the line structures to which it is applicable, and this application does not make specific restrictions on this. For example, the third connection portion 103 may also be a line structure extending in other directions); or, the third connection line portion 103 may also belong to the first connection line portion 101, and may be the portion of the first connection line portion 101 that does not overlap with the signal transmission line 20, such as the portion of the first connection line portion 101 between two adjacent first intermediate signal transmission lines 210 and the portion outside the two adjacent first intermediate signal transmission lines 210 shown in FIG. 14 may be set as the third connection line part 103. The line width d14 of the third connection line part 103 may be prepared to be larger than the line width d12 of the second connection line portion 102, which may effectively reduce the impedance of the device connection line 100 and improve the signal transmission performance of the device connection line 100.

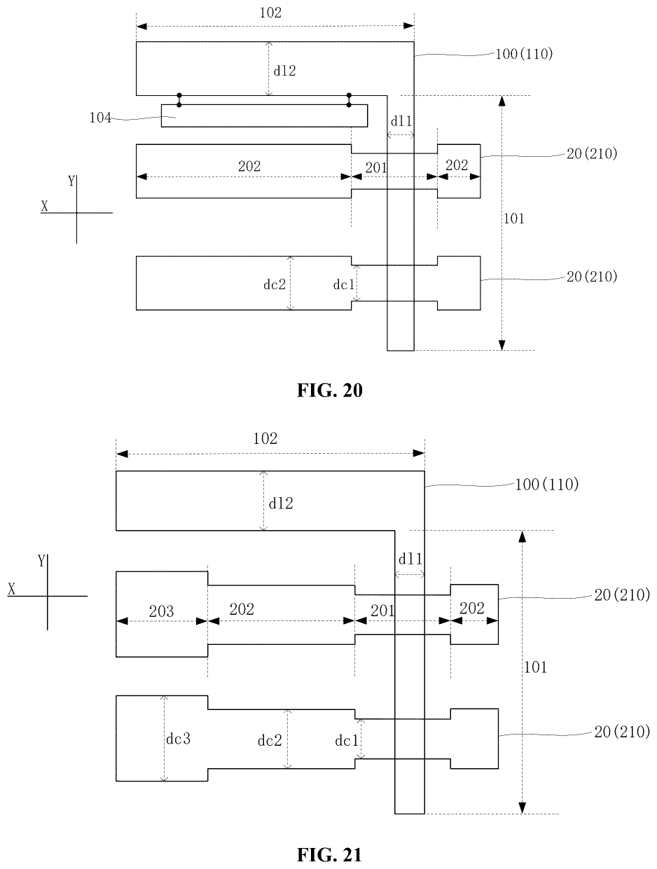

In some embodiments, to reduce the impedance of the device connection line 100, a line parallel to the second connection line portion 102 may be set. As shown in FIG. 20, when the line width dl1 of the first connection line portion 101 at the overlapping area with the first transmission line portion 201 is smaller than the line width dl2 of the second connection line portion 102, the device connection line 100 may further include a parallel connection line portion 104, and the parallel connection line portion 104 may be connected in parallel with the second connection line portion 102. The parallel connection line portion 104 may be arranged at the same layer as the second connection line portion 102, and the parallel connection line portion 104 and the second connection line portion 102 may be connected in parallel through the lines at the same layer. Alternatively, when the parallel connection line portion 104 and the second connection line portion 102 are arranged in different layers, the parallel connection line portion 104 and the second connection line portion 102 may be connected in parallel by a via connection, and in the direction perpendicular to the plane where the display panel is located, the parallel connection line portion 104 and the second connection line portion 102 may at least partially overlap in the extension direction, which may not only reduce the impedance of the device connection line 100, but also reduce the occupied area of the device connection line 100 by designing that the parallel connection line portion 104 and the second connection line portion 102 overlap in the extension direction, thereby ensuring that the effective wiring panel of the display panel may be larger.

Similarly, at the overlapping area of the first connection line portion 101 and the first transmission line portion 201, narrowing the line width of at least one of the first connection line portion 101 and the first transmission line portion 201 may reduce the coupling interference problem at the overlapping area of the connection line 100 and the signal transmission line 20. On this basis, the signal transmission line 20 may also be further optimized. As shown in FIG. 21, in some embodiments, the line width dc1 of the first transmission line portion 201 may be smaller than the line width dc2 of the second transmission line portion 202, and the signal transmission line 20 may further include a third transmission line portion 203, and the line width dc3 of the third transmission line portion 203 may be larger than the line width dc2 of the second transmission line portion 202. The provision of the third transmission line portion 203 may be equivalent to widening the overall width of the signal transmission line 20, thereby reducing the impedance of the signal transmission line 20 and improving the signal transmission performance of the signal transmission line 20.

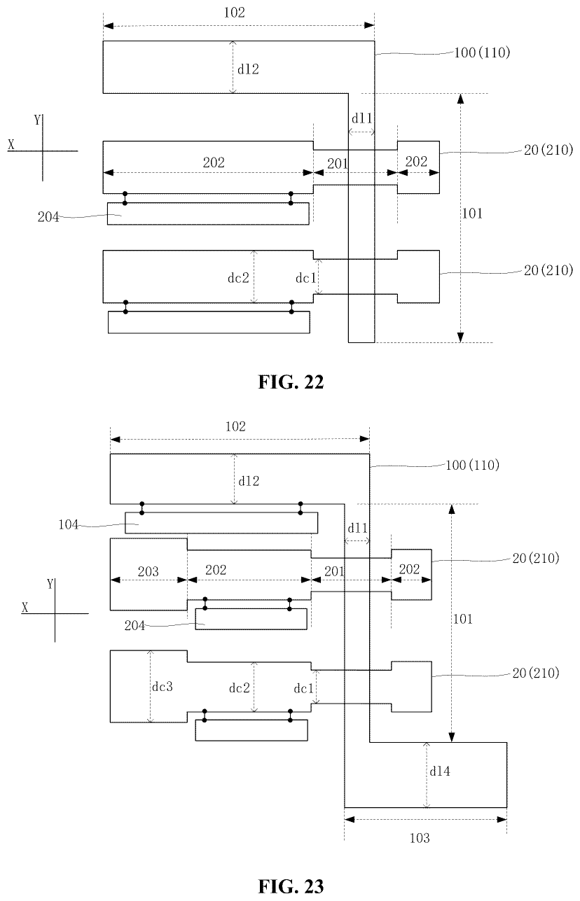

In some embodiments, to reduce the impedance of the signal transmission line 20, a line parallel to the second transmission line portion 202 may be provided. Specifically, as shown in FIG. 22, the line width dc1 of the first transmission line portion 201 may be smaller than the line width dc2 of the second transmission line portion 202, and the signal transmission line 20 may further include a parallel transmission line portion 204, which may be connected in parallel with the second transmission line portion 202. Among them, the parallel transmission line portion 204 and the second transmission line portion 202 may be arranged in the same layer, and then the parallel transmission line 204 and the second transmission line 202 may be connected in parallel through the same layer line; or, the parallel transmission line portion 204 and the second transmission line part 202 may be arranged in different layers, and the parallel transmission line portion 204 and the second transmission line portion 202 may be connected by a via connection method, and in the direction perpendicular to the plane where the display panel is located, the parallel transmission line portion 204 and the second transmission line portion 202 may at least partially overlap in the extension direction, which may not only reduce the impedance of the signal transmission line 20, but also reduce the occupied area of the signal transmission line 20 by designing that the parallel transmission line portion 204 and the second transmission line portion 202 overlap in the extension direction, so as to ensure that the effective wiring area of the display panel may be large.

It should be noted that the display panel provided in the embodiment of the present disclosure may include any one of the third connection line portion 103, the parallel connection line part 104, the third transmission line portion 203 and the parallel transmission line portion 204. Alternatively, the display panel may include a combination of at least two of the third connection line portion 103, the parallel connection line portion 104, the third transmission line portion 203 and the parallel transmission line portion 204. FIG. 23 illustrates the display panel including all structures of the third connection line portion 103, the parallel connection line portion 104, the third transmission line portion 203 and the parallel transmission line portion 204, and this disclosure does not impose any specific restrictions on this.

In addition to adopting the above-mentioned line width narrowing optimization design for the device connection line 100 and the signal transmission line 20 to reduce the coupling interference between the device connection line 100 and the signal transmission line 20, a hole may also be formed at the overlapping area of the device connection line 100 and the signal transmission line 20 to achieve the purpose of reducing the coupling interference between the device connection line 100 and the signal transmission line 20.

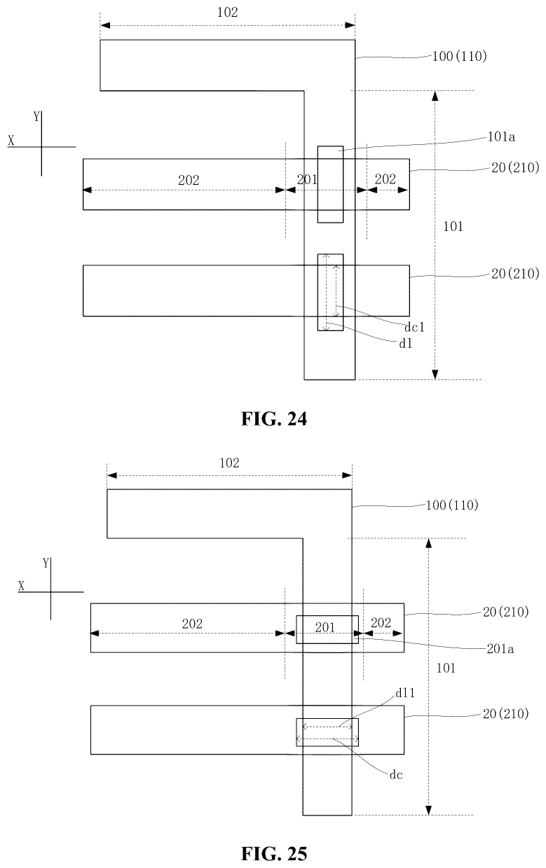

As shown in FIG. 24, the pixel driving circuit 10 may include a plurality of device connection lines 100. The plurality of device connection lines 100 may include a gate device connection line 110; at least one device connection line 100 may include at least a first connection line portion 101 extending along a second direction Y, and the at least one device connection line 100 may also include a second connection line portion 102. At least one signal transmission line 20 may include a first transmission line portion 201 and a second transmission line portion 202. In a direction perpendicular to the plane where the display panel is located, at least one first connection line portion 101 may intersect with at least one first transmission line portion 201. The first connection line portion 101 of the gate device connection line 110 may overlap with at least two first transmission line portions 201. At the overlapping area of the first connection line portion 101 and the first transmission line portion 201, the first connection line portion 101 may include at least one connection hollowed hole 101a overlapping with the first transmission line portion 201 to reduce the overlapping area of the first connection line portion 101 and the first transmission line portion 201, thereby reducing the coupling interference problem at the overlapping area of the device connection line 100 and the signal transmission line 20, improving the signal transmission effect of the line, and ensuring the high performance of the display panel. In another embodiment, the first connection line portion 101 may be a line extending along the second direction Y, so the connection hollowed hole 101a may be a hole extending along the second direction Y.

Similarly, to achieve the purpose of reducing the coupling interference problem at the overlapping area of the device connection line 100 and the signal transmission line 20, in some embodiments, the first transmission line portion 201 may also be processed by forming a hole. As shown in FIG. 25, the pixel driving circuit 10 may include a plurality of device connection lines 100; the plurality of device connection lines 100 may include a gate device connection line 110; at least one device connection line 100 may include at least a first connection line portion 101 extending along a second direction Y; and the at least one device connection line 100 may also include a second connection line portion 102. At least one signal transmission line 20 may include a first transmission line portion 201 and a second transmission line portion 202. In a direction perpendicular to the plane where the display panel is located, at least one first connection line portion 101 may overlap with at least one first transmission line portion 201, and the first connection line portion 101 of the gate device connection line 110 may overlap with at least two first transmission line portions 201. At the overlapping area of the first connection line portion 101 and the first transmission line portion 201, the first transmission line portion 201 may include at least one transmission hollow hole 201a overlapping with the first connection line portion 101 to reduce the overlapping area of the first connection line portion 101 and the first transmission line portion 201. In one embodiment, the first transmission line portion 201 may be a line extending along the first direction X, so the transmission hollowed hole 201a may be a hole extending along the first direction X.

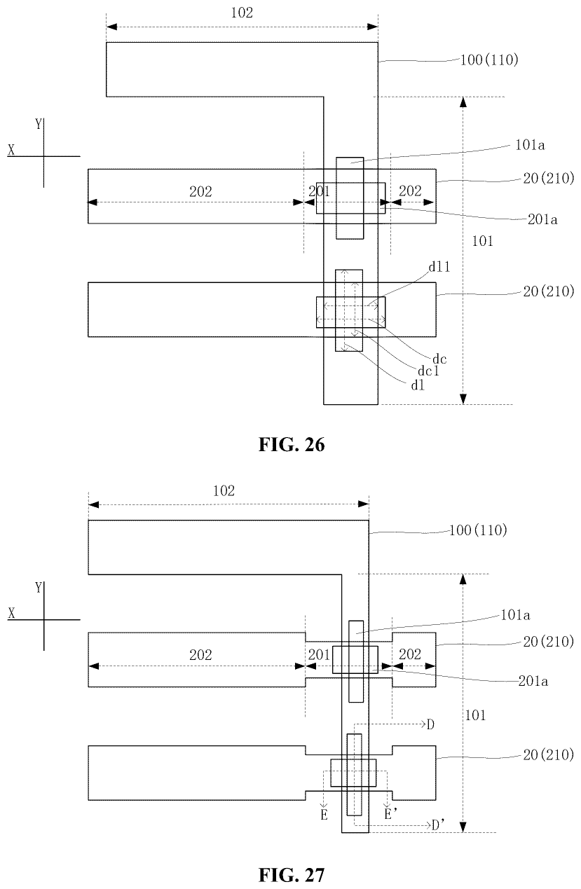

In addition, the first connection line portion 101 and the first transmission line portion 201 may also be processed by forming holes at the same time to reduce the overlapping area of the first connection line portion 101 and the first transmission line portion 201. As shown in FIG. 26, at the overlapping area of the first connection line portion 101 and the first transmission line portion 201, the first connection line portion 101 may include at least one connection hollowed hole 101a overlapping with the first transmission line portion 201, and the first transmission line portion 201 may include at least one transmission hollowed hole 201a overlapping with the first connection line portion 101.

Combined with FIG. 24 to FIG. 26, in the second direction Y, the width d1 of the connection hollowed hole 101a may be greater than the width dc1 of the first transmission line portion 201, and the orthographic projections of the inner walls on both sides of the connection hollowed hole 101a on the substrate may be both located outside the orthographic projection of the first transmission line portion 201 on the substrate, thereby reducing the coupling interference between the edge of the first transmission line portion 201 and the edge of the connection hollowed hole 101a in the second direction Y. Also, in the first direction X, the width dl of the transmission hollowed hole 201a may greater than the width dl1 of the first connection line portion 101, and the orthographic projections of the inner walls on both sides of the transmission hollowed hole 201a on the substrate may be both located outside the orthographic projections of the first connecting line portion 101 on the substrate, thereby reducing the coupling interference between the edge of the first connection line portion 101 and the edge of the transmission hollowed hole 201a in the first direction X, and ultimately achieving the purpose of reducing the coupling interference between the device connection line 100 and the signal transmission line 20.

In the display panel, the coupling interference problem between the device connection line 100 and the signal transmission line 20 may be reduced by only optimizing the line width narrowing method at the overlapping area of the device connection line 100 and the signal transmission line 20; the coupling interference problem between the device connection lines 100 and 20 may also be reduced by only preparing hollowed holes at the overlapping area of the device connection line 100 and the signal transmission line 20. Further, the coupling interference problem between the device connection lines 100 and 20 may be reduced by both optimizing the line width narrowing method at the overlapping area of the device connection line 100 and the signal transmission line 20 and preparing hollowed holes at the overlapping area of the device connection line 100 and the signal transmission line 20. The selection of these methods may need to be determined according to the actual application.

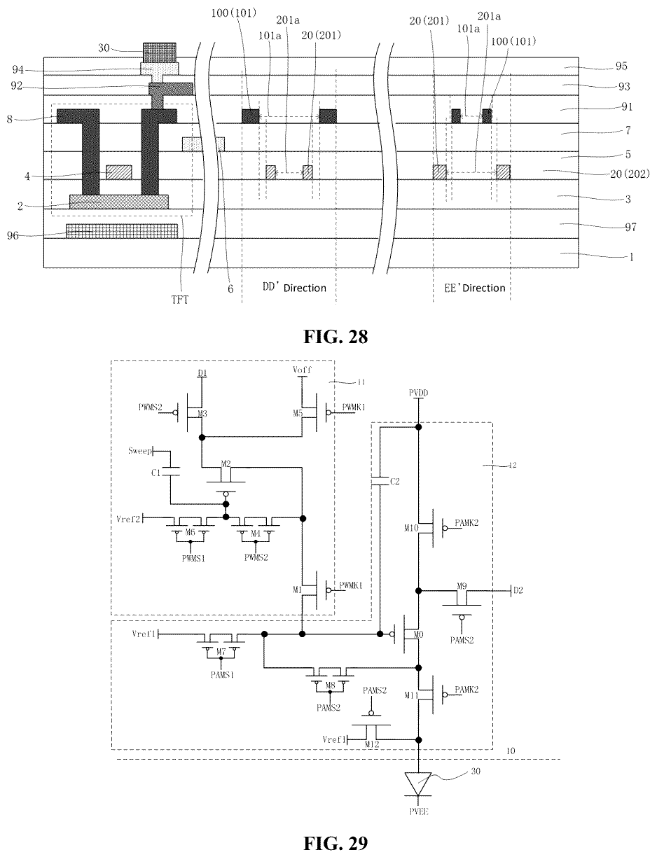

FIG. 28 illustrates a DD′ and EE′-sectional view in FIG. 27. FIG. 27 and FIG. 28 illustrate a method of optimizing the line width narrowing at the overlapping area of the device connection line 100 and the signal transmission line 20, and preparing a hollowed hole at the overlapping area of the device connection line 100 and the signal transmission line 20 to reduce the coupling interference problem between the device connection lines 100 and the signal transmission line 20. The present application does not make specific restrictions on this.

Based on the circuit design ideas provided in any of the above embodiments, a specific pixel driving circuit 10 and its circuit layout design provided in the present disclosure are described below in combination with the accompanying drawings to explain the technical solution provided in the present disclosure in more detail. It should be noted that the specific pixel driving circuit 10 is only one of all circuits applicable to the display panel provided in the present disclosure. In other embodiments of the present disclosure, the pixel driving circuit 10 may also be composed and connected in other ways.

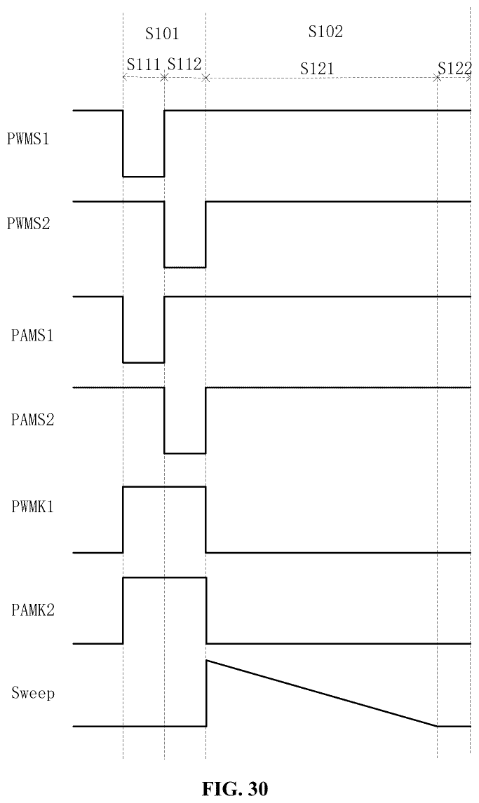

As shown in FIGS. 29-30, the pixel driving circuit 10 may include a first partial circuit 11 and a second partial circuit 12. The first partial circuit 11 may be a pulse width modulation unit, and the second partial circuit 12 may be an amplitude modulation unit. The pulse width modulation unit 11 may include a first transistor M1, a second transistor M2, a third transistor M3, a fourth transistor M4, a fifth transistor M5, a sixth transistor M6 and a first capacitor C1. The amplitude modulation unit 12 may include a seventh transistor M7, an eighth transistor M8, a ninth transistor M9, a tenth transistor M10, an eleventh transistor M11, a twelfth transistor M12 and a second capacitor C2.

The first terminal of the sixth transistor M6 may be electrically connected to the second reference voltage line Vref2, and the second terminal of the sixth transistor M6 may be electrically connected to all of the gate of the second transistor M2, the first terminal of the fourth transistor M4 and the second terminal of the first capacitor C1. The gate of the sixth transistor M6 may be electrically connected to the first pulse width scanning control signal line PWMS1. The first terminal of the first capacitor C1 may be electrically connected to the pulse width control voltage line Sweep. The pulse width control voltage line Sweep may be configured to transmit a linear decreasing voltage. The first terminal of the second transistor M2 may be electrically connected to both the second terminal of the third transistor M3 and the second terminal of the fifth transistor M5. The second terminal of the second transistor M2 may be electrically connected to the second terminal of the fourth transistor M4 and the first terminal of the first transistor M1. The first terminal of the third transistor M3 may be electrically connected to the first data voltage line D1. The gate of the third transistor M3 may be electrically connected to the second pulse width scanning control signal line PWMS2. The first terminal of the fifth transistor M5 may be electrically connected to the turn-off voltage line Voff. The gate of the fifth transistor M5 may be electrically connected to the first light-emitting control signal line PWMK1. The second terminal of the first transistor M1 may be electrically connected to the gate of the driving transistor M0, and the gate of the first transistor M1 may be electrically connected to the first light-emitting control signal line PWMK1.

Further, referring to FIG. 29, the first terminal of the seventh transistor M7 may be electrically connected to the first reference voltage line Vref1, and the second terminal of the seventh transistor M7 may be electrically connected to all of the gate of the driving transistor M0, the second terminal of the eighth transistor M8, and the second terminal of the second capacitor C2. The gate of the seventh transistor M7 may be electrically connected to the first amplitude scanning control signal PAMS1, the first terminal of the eighth transistor M8 may be electrically connected to the second terminal of the driving transistor M0, the gate of the eighth transistor M8 may be electrically connected to the second amplitude scanning control signal PAMS2, and the first terminal of the second capacitor C2 may be connected to the power supply voltage PVDD. The first terminal of the ninth transistor M9 may be electrically connected to the second data voltage line D2, the second terminal of the ninth transistor M9 may be electrically connected to the first terminal of the driving transistor M0, and the gate of the ninth transistor M9 is electrically connected to the second amplitude scanning control signal line PAMS2. The first terminal of the tenth transistor M10 may be electrically connected to the power supply voltage PVDD, the second terminal of the tenth transistor M10 may be electrically connected to the first terminal of the driving transistor M0, and the gate of the tenth transistor M10 may be electrically connected to the second light-emitting control signal line PAMK2. The first terminal of the eleventh transistor M11 may be electrically connected to the second terminal of the driving transistor M0, the second terminal of the eleventh transistor M11 may be electrically connected to the first terminal of the light-emitting element 30, the gate of the eleventh transistor M11 may be electrically connected to the second light-emitting control signal line PAMK2, the first terminal of the twelfth transistor M12 may be electrically connected to the first reference voltage line Vref1, the second terminal of the twelfth transistor M12 may be electrically connected to the first terminal of the light-emitting element 30, the gate of the twelfth transistor M12 may be electrically connected to the second amplitude scanning control signal line PAMS2, and the second terminal of the light-emitting element 30 may be connected to the cathode voltage PVEE. In one embodiment, the fourth transistor M4, the sixth transistor M6, the seventh transistor M7 and the eighth transistor M8 may be dual-gate transistors to improve the response speed of the transistors and improve the performance of the pixel driving circuit 10.

The voltages transmitted by different signal transmission lines 20 as shown in FIG. 13 describe the working principle of the pixel driving circuit 10. The embodiment of the present disclosure takes all the transistors in the pixel driving circuit 10 are all P-type transistors as an example. In other embodiments of the present disclosure, the transistors of the pixel driving circuit 10 may also be N-type transistors, and the present disclosure does not make specific restrictions on this.

The driving method of the pixel driving circuit 10 may include a signal generation stage S101 and a light-emitting control stage S102 which may be performed in sequence. The signal generation stage S101 may include a first sub-signal generation stage S111 and a second sub-signal generation stage S112 which may be performed in sequence. In the signal generation stage S101, the first light-emitting control signal line PAMK1 and the second light-emitting control signal line PAMK2 may be output as high level to control the connected transistors to be cut off. In the first sub-signal generation stage S111, the first pulse width scanning control signal PWMS1 and the first amplitude scanning control signal line PAMS1 may be output as low level, while the second pulse width scanning control signal PWMS2 and the second amplitude scanning control signal line PAMS2 may be output as high level. At this time, the sixth transistor M6 and the seventh transistor M7 may be controlled to be turned on, the second reference voltage line Vref2 may transmit the second reference voltage to the gate of the second transistor M2, and the first reference voltage line Vref1 may transmit the first reference voltage to the gate of the driving transistor M0 to reset the second transistor M2 and the driving transistor M0. At this time, the transistor whose gate is connected to the second pulse width scanning control signal PWMS2 and the second amplitude scanning control signal PAMS2 may be controlled to be turned off.

Then, in the second sub-signal generation phase S112, the first pulse width scanning control signal line PWMS1 and the first amplitude scanning control signal line PAMS1 may be both output as high level, while the second pulse width scanning control signal line PWMS2 and the second amplitude scanning control signal line PAMS2 may be both output as low level. At this time, the third transistor M3, the fourth transistor M4, the eighth transistor M8 and the ninth transistor M9 may be turned on, and the first data voltage transmitted by the first data voltage line D1 may be transmitted to the gate of the second transistor M2 through the third transistor M3, the second transistor M2 and the fourth transistor M4, completing the writing of the first data voltage, that is, completing the generation process of the pulse width setting signal; and the second data voltage transmitted by the second data voltage line D2 may be transmitted to the gate of the driving transistor M0 through the ninth transistor M9, the driving transistor M0 and the eighth transistor M8, completing the writing of the second data voltage, that is, completing the process of transmitting the amplitude setting signal to the gate of the driving transistor M0. At the same time, the conductor of the twelfth transistor M12 may transmit the first reference voltage output by the first reference voltage line Vref1 to the light-emitting element 30 to keep it off.

The light-emitting control stage S102 may include a light-emitting sub-stage S121 and an turn-off sub-stage S122 which may be performed sequentially. In the light-emitting stage S102, the first pulse width scanning control signal line PWMS1, the first amplitude scanning control signal line PAMS1, the second pulse width scanning control signal line PWMS2 and the second amplitude scanning control signal PAMS2 may be all output as high levels, and the connected transistors may be controlled to be turned off. In the light-emitting sub-stage S121, the first light-emitting control signal line PWMK1 and the second light-emitting control signal line PAMK2 may be both output as a low level, controlling the fifth transistor M5, the first transistor M1, the tenth transistor M10 and the eleventh transistor M11 to be turned on. At this time, the pulse width control voltage output by the pulse width control voltage line Sweep may control the second transistor M2 to remain off through the first capacitor C1. Although the fifth transistor M5 may be turned on, the turn off voltage transmitted by the turn-off voltage line Voff may not be transmitted to the gate of the driving transistor M0 through the second transistor M2. At this time, the pulse width setting signal transmitted by the first transistor M1 may be essentially a floating signal; the tenth transistor M10 and the eleventh transistor M11 may be turned on to turn on the path from the power supply voltage PVDD to the cathode voltage PVEE, and the driving current generated by the driving transistor M0 may be transmitted to the light-emitting element 30. Then, in the turn-off sub-stage S122, the first light-emitting control signal line PWMK1 and the second light-emitting control signal line PAMK2 may be both output as low levels, and the corresponding transistors may be controlled to be turned on; and the pulse width control voltage transmitted by the pulse width control voltage line Sweep may be a ramp voltage of a linearly decreasing voltage, which may drop to the lowest level at this stage and may not be maintained by the first capacitor C1 to keep the second transistor M2 turned off and controlled to be turned on, and the turn-off voltage transmitted by the turn-off voltage line Voff may be transmitted to the gate of the driving transistor M0 through the fifth transistor M5, the second transistor M2 and the first transistor M1 to control the driving transistor M0 to be turned off. At this time, the driving transistor M0 may no longer generate a driving current, and the light-emitting element 30 may remain off.

Based on the equivalent circuit of the pixel driving circuit 10 described above, the equivalent circuit is combined with the line width narrowing design, hole forming design and other ideas described above, and a layout design of the pixel driving circuit 10 is described in detail.

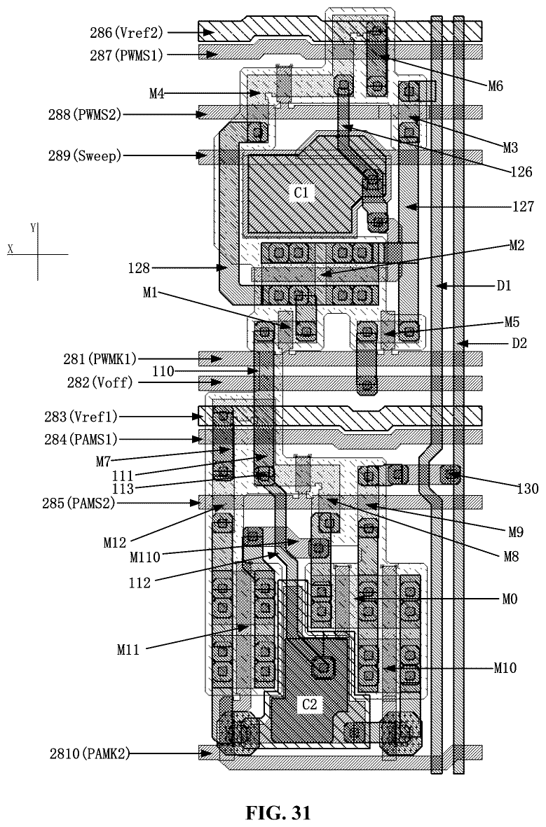

Specifically, as shown in FIG. 31, the first partial circuit 11 may include a pulse width modulation unit of the pixel driving circuit 10, and the second partial circuit 12 may include an amplitude modulation unit of the pixel driving circuit 10. The pulse width modulation unit 11 (the pulse width modulation unit label is set to be the same as the first partial circuit 11) may include a first transistor M1, and the amplitude modulation unit 12 (the amplitude modulation unit label is set to be the same as the second partial circuit 12) may include a driving transistor M0. The second terminal of the first transistor M1 may be electrically connected to the gate of the driving transistor M0 through a gate device connection line 110. In the direction from the first partial circuit 11 to the second partial circuit 12, all the second intermediate signal transmission lines 220, the first intermediate signal transmission line 210 and the third intermediate signal transmission line 230 may be defined as a first intermediate signal transmission line 281 to the N-th intermediate signal transmission line 28n arranged in sequence. N may be an integer greater than or equal to 2. The second terminal of the first transistor M1 may be located at the side of the first intermediate signal transmission line 281 away from the N-th intermediate signal transmission line 28n, and the gate of the driving transistor M0 may be located at the side of the N-th intermediate signal transmission line 28n away from the first intermediate signal transmission line 281. In a direction perpendicular to the plane where the display panel is located, the gate device connection line 110 may be insulated and crossed with the first intermediate signal transmission line 281 to the N-th intermediate signal transmission line 28n.

FIG. 31 shows an example in which N is 5. Because the intermediate signal transmission lines may be all signal transmission lines 20 set between the first capacitor C1 and the second capacitor C2, the first intermediate signal transmission line 281 to the fifth intermediate signal transmission line 285 may be included between the first capacitor C1 and the second capacitor C2. The gate device connection line 110 may be insulated and crossed with the first intermediate signal transmission line 281 to the fifth intermediate signal transmission line 285 in the path connecting the second terminal of the first transistor M1 and the gate of the driving transistor M0. Thus, by setting a plurality of intermediate signal transmission lines in the middle area where the first partial circuit 11 and the second partial circuit 12 of the pixel driving circuit 10 are opposite, and some of the intermediate signal transmission lines may also pass through the inside of the second partial circuit 12, the connection between the transistor and the signal transmission line 10 in the pixel driving circuit 10 may be simplified, and the line length of the device connection line 100 may be shortened, reducing the signal interference problem of other lines on the device connection line 100.

Furthermore, an edge signal transmission line may be arranged along the edge direction of the pixel driving circuit 10 along the second direction Y, so as to facilitate the connection between the signal transmission line 20 and the transistor in the pixel driving circuit 10. Referring to FIG. 31, along the direction from the first partial circuit 11 to the second partial circuit 12, the plurality of signal transmission lines 20 may include a first edge signal transmission line 286, a second edge signal transmission line 287, a third edge signal transmission line 288, a fourth edge signal transmission line 289, a first intermediate signal transmission line 281, a second intermediate signal transmission line 282, a third intermediate signal transmission line 283, a fourth intermediate signal transmission line 284, a fifth intermediate signal transmission line 285 and a fifth edge signal transmission line 2810 arranged in sequence. The first edge signal transmission line 286 to the fourth edge signal transmission line 289 may be located at the side of the first capacitor C1 away from the second circuit 12; the first intermediate signal transmission line 281 to the fifth intermediate signal transmission line 285 may be located between the first capacitor C1 and the second capacitor C2; and the fifth edge signal transmission line 2810 may be located at the side of the second circuit 12 away from the first circuit 11. By optimizing the layout of the edge signal transmission lines and the intermediate signal transmission lines in the pixel driving circuit 10, the transistors at the edge and the transistors in the middle of the pixel driving circuit 10 may be adjacent to their respective corresponding signal transmission lines 20, which may reduce the connection difficulty and distance between the signal transmission lines 20 and the transistors in the pixel driving circuit 10.

As shown in FIG. 29, the plurality of signal transmission lines 20 may include a first reference voltage line Vref1, a second reference voltage line Vref2, a first pulse width scanning control signal line PWMS1, a second pulse width scanning control signal line PWMS2, a first amplitude scanning control signal line PAMS1, a second amplitude scanning control signal line PAMS2, a first light-emitting control signal line PWMK1, a second light-emitting control signal line PAMK2, a turn-off voltage line Voff and a pulse width control voltage line Sweep. As shown in FIG. 31, the first edge signal transmission line 286 may be the second reference voltage line Vref2; the second edge signal transmission line 287 may be the first pulse width scanning control signal line PWMS1; the third edge signal transmission line 288 may be the second pulse width scanning control signal line PWMS2; the fourth edge signal transmission line 289 may be the pulse width control voltage line Sweep; the first intermediate signal transmission line 281 may be the first light emission control signal line PWMK1; the second intermediate signal transmission line 282 may be the turn-off voltage line Voff; the third intermediate signal transmission line 283 may be the first reference voltage line VREF1; the fourth intermediate signal transmission line 284 may be the first amplitude scanning control signal line PAMS1; the fifth intermediate signal transmission line 285 may be the second amplitude scanning control signal line PAMS2; and the fifth edge signal transmission line 2810 may be the second light-emitting control signal line PAMK2. Based on the distribution setting of the signal transmission line 20, the distribution of transistors and capacitors of the pulse width modulation unit 11 and the amplitude modulation unit 12 may be optimized to reduce the connection difficulty between the transistors and the signal transmission line 20.

In one embodiment, the pulse width modulation unit 11 may include a fourth transistor M4, a sixth transistor M6 and a third transistor M3 arranged in sequence along the first direction X, a first capacitor C1 located on the side of the sixth transistor M6 facing the second part of the circuit 12, a second transistor M2 located on the side of the first capacitor C1 facing the second part of the circuit 12, and a first transistor M1 and a fifth transistor M5 located on the side of the second transistor M2 facing the second partial circuit 12 and arranged in sequence along the first direction X.

Further, referring to FIG. 31, the amplitude modulation unit 12 may include a seventh transistor M7, a twelfth transistor M12, an eighth transistor M8 and a ninth transistor M9 located at the side of the seventh transistor M7 facing the second light-emitting control signal line PAMK2 and arranged in sequence along the first direction X, an eleventh transistor M11 and a driving transistor M0 located at the side of the eighth transistor M8 facing the second light-emitting control signal line PAMK2 and arranged in sequence along the first direction X, and a second capacitor C2 and a tenth transistor M10 located at the side of the driving transistor M0 facing the second light-emitting control signal line PAMK2 and arranged in sequence along the first direction X. It can be understood that the electrically connected transistors, capacitors and signal transmission lines 20 may be arranged nearby, which may facilitate the electrical connection between the transistors, capacitors and signal transmission lines 20. For example, in the pulse width modulation unit 11, the first capacitor C1, the fourth transistor M4, the sixth transistor M6 and the third transistor M3 may be arranged nearby the first pulse width scanning control signal line PWMS1, the second pulse width scanning control signal line PWMS2, the pulse width control voltage line Sweep and the second reference voltage line Vref2, and the first transistor M1, the second transistor M2 and the fifth transistor M5 may be arranged nearby the first light-emitting control signal line PWMK1 and the turn-off voltage line Voff; and in the amplitude modulation unit 12, the seventh transistor M7 may be set nearby the first amplitude scanning control signal PAMS1 and the first reference voltage line Vref1, the eighth transistor M8, the ninth transistor M9 and the twelfth transistor M12 may be set nearby the first reference voltage line Vref1, the first amplitude scanning control signal PAMS1 and the second amplitude scanning control signal line PAMS2, the driving transistor M0, the tenth transistor M10 and the second capacitor C2 may be set nearby, and the tenth transistor M10 and the eleventh transistor M11 may be set nearby the second light-emitting control signal line PAMK2.

Furthermore, some transistors in the pixel driving circuit 10 may also overlap with some signal transmission lines 20, which may not only reduce the wiring area of the pixel driving circuit 10 and the signal transmission line 20, but also reduce the film preparation and reduce the preparation process flow by multiplexing some line segments of the signal transmission line 20 by transistors. Further, referring to FIG. 31, the pixel driving circuit 10 is described in the direction from the first partial circuit 11 to the second partial circuit 12. In the orthographic projection on the substrate, in the pulse width modulation unit 11, the sixth transistor M6 may overlap with the first pulse width scanning control signal line PWMS1, and the gate of the sixth transistor M6 may multiplex some line segments of the first pulse width scanning control signal line PWMS1. The first capacitor C1 may extend between the second pulse width scanning control signal line PWMS2 and the pulse width control voltage line Sweep, thereby increasing the area of the first capacitor C1, so that the first capacitor C1 may better stabilize the potential of the terminal connected to it. The second terminal of the sixth transistor M6 may be electrically connected to the second terminal of the first capacitor C1 through the sixth device connection line 126, and the sixth device connection line 126 may at least cross the second pulse width scanning control signal line PWMS2. The sixth device connection line 126 may be divided into two parts, one part may cross both the second reference voltage line Vref2 and the first pulse width scanning control signal line PWMS1, and the other part may cross the second pulse width scanning control signal line PWMS2, and the two parts of the sixth device connection line 126 may be connected by a via. The third transistor M3 may overlap with the second pulse width scanning control signal line PWMS2, and the gate of the third transistor M3 may multiplex a part of the line segment of the second pulse width scanning control signal line PWMS2, and the second terminal of the third transistor M3 may be electrically connected to the first terminal of the second transistor M2 through the seventh device connection line 127, and the seventh device connection line 127 may cross the pulse width control voltage line Sweep. The fourth transistor M4 may overlap with the second pulse width scanning control signal line PWMS2, and the second terminal of the fourth transistor M4 may be electrically connected to the second terminal of the second transistor M2 through the eighth device connection line 128, and the eighth device connection line 128 may intersect with the pulse width control voltage line Sweep. The first capacitor C1 may be located in the area surrounded by the second pulse width scanning control signal line PWMS2, the seventh device connection line 127, the second transistor M2 and the eighth device connection line 128, and the first capacitor C1 may be designed with a larger area, so as to better stabilize the potential of the terminal connected to the first capacitor C1. The fifth transistor M5 may be connected to the turn-off voltage line Voff using a device connection line 100 intersecting with the first light-emitting control signal line PWMK1.

Further, as shown in FIG. 31, in the amplitude modulation unit 12, the seventh transistor M7 may overlap with the first amplitude scanning control signal line PAMS1, and the gate of the seventh transistor M7 may multiplex a part of the line segment of the first amplitude scanning control signal line PAMS1; at least one of the eighth transistor M8, the ninth transistor M9 and the twelfth transistor M12 may overlap with the second amplitude scanning control signal line PAMS2, and the gate of at least one of the eighth transistor M8, the ninth transistor M9 and the twelfth transistor M12 may multiplex a portion of the line segment of the second amplitude scanning control signal line PAMS2. Among them, the second capacitor C2 may be located in the surrounding area of the eleventh transistor M11, the driving transistor M0, the tenth transistor M10 and the second light emitting control signal line PAMK2, and the area of the second capacitor C2 may be increased to stabilize the potential of the gate of the driving transistor M0, thereby improving the performance of the pixel driving circuit 10.

In some embodiments, the capacitance of the first capacitor C1 shown in FIG. 31 may be slightly larger than the capacitance of the second capacitor C2, for example, the capacitance ratio of the first capacitor C1 to the second capacitor C2 may be approximately 1.04, the first capacitor C1 may be 1350 f, and the second capacitor C2 may be 1300 f. The grayscale control of the pixel driving circuit 10 may be achieved by controlling the duration of the pulse width modulation unit to turn on or off the amplitude modulation unit. The stability of the potential at the gate of the second transistor M2 may affect the grayscale segmentation. Increasing the capacitance of the first capacitor C1 may be conducive to improving the stability of the potential at the gate of the second transistor M2.

It should be noted that, in the display panel, the display panel may adopt a combination of at least one or more of the following overlapping methods: the sixth transistor M6 overlaps with the first pulse width scanning control signal line PWMS1, the third transistor M3 overlaps with the second pulse width scanning control signal line PWMS2, the fourth transistor M4 overlaps with the second pulse width scanning control signal line PWMS2, the seventh transistor M7 overlaps with the first amplitude scanning control signal line PAMS1, the eighth transistor M8 overlaps with the second amplitude scanning control signal line PAMS2, the ninth transistor M9 overlaps with the second amplitude scanning control signal line PAMS2, and the twelfth transistor M12 overlaps with the second amplitude scanning control signal line PAMS2. In addition, the device connection line 100 may be an integrated connection structure made of the same metal layer; or the device connection line 100 may be divided into multiple parts, different parts may be located in different metal layers, and different parts may be connected together by vias, such as the gate device connection line 110 shown in FIG. 31. The gate device connection line 110 may include a first part 111 and a second part 112. The first part 111 and the second part 112 may be located in different metal layers, and the first part 111 and the second part 112 may be connected as a connection line by a via 113 to electrically connect the second terminal of the first transistor M1 and the gate of the driving transistor M0. In addition, the device connection line 100 may directly connect the terminals of two components, or the device connection line 100 may connect the terminals of two components indirectly. Similarly, as shown in FIG. 31, the first part 111 of the gate device connection line 110 may be directly connected to the second terminal of the first transistor M1, and then the first part 111 may be connected to the second part 112 using the via 113, and the second part 112 may be connected to the second terminal of the second capacitor C2. Similarly, since the gate of the driving transistor M0 may be connected to the second terminal of the second capacitor C2, the second part 112 may be indirectly connected to the gate of the driving transistor M0 through the second terminal of the second capacitor C2. In addition, the connection line M110 between the first terminal of the eleventh transistor M11 and the second terminal of the driving transistor M0 shown in FIG. 31 may be designed to have a larger line width, for example, the line width of the connection line M110 may be designed to be greater than the line width of the second part 112 of the gate device connection line 110, thereby reducing the routing resistance of the connection line M110 and improving its current resistance and charging capabilities.

In addition, the metal layers where different signal transmission lines 20 are located may be the same, for example, all signal transmission lines 20 may be formed by the gate metal layer 3. Alternatively, some signal transmission lines 20 may be formed by the gate metal layer 3, and some signal transmission lines 20 may be formed by the capacitor metal layer 6. For example, the first reference voltage line Vref1 and the second reference voltage line Vref2 may be formed by the capacitor metal layer 6, and the first pulse width scanning control signal line PWMS1, the second pulse width scanning control signal line PWMS2, the first amplitude scanning control signal line PAMS1, the second amplitude scanning control signal line PAMS2, the first light-emitting control signal line PWMK1, the second light-emitting control signal line PAMK2, the turn-off voltage line Voff and the pulse width control voltage line Sweep may be formed by the gate metal layer 3, and this disclosure does not make specific restrictions.

In addition, at the overlapping area of the device connection line 100 and the signal transmission line 20, at least one of the device connection line 100 and the signal transmission line 20 may be designed with line width narrowing and/or hole forming to reduce the coupling interference between the device connection line 100 and the signal transmission line 20. The technical solution provided by the present disclosure is described in detail below by using a schematic diagram of a pixel driving circuit 10 having a device connection line 100 and a signal transmission line 20 with a line width narrowing optimization design.

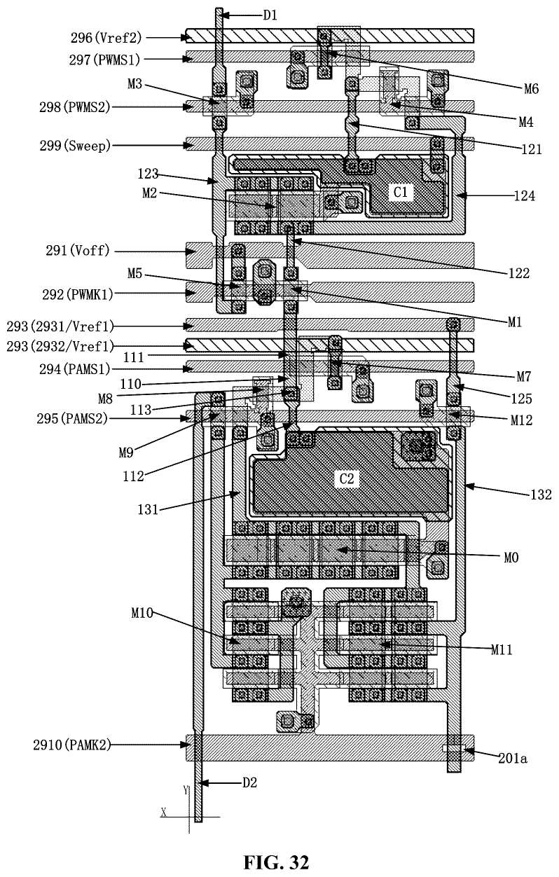

Specifically, referring to FIG. 32, the first partial circuit 11 may include a pulse width modulation unit of the pixel driving circuit 10, and the second partial circuit 12 may include an amplitude modulation unit of the pixel driving circuit 10. The pulse width modulation unit 11 may include a first transistor M1, and the amplitude modulation unit 12 may include a driving transistor M0. The second terminal of the first transistor M1 may be electrically connected to the gate of the driving transistor M0 through a gate device connection line 110. Along the direction from the first partial circuit 11 to the second partial circuit 12, all the second intermediate signal transmission line 220, the first intermediate signal transmission line 210 and the third intermediate signal transmission line 230 may defined as the first intermediate signal transmission line 291 to the N-th intermediate signal transmission line 29n arranged in sequence. N may be greater than or equal to 2. The second terminal of the first transistor M2 may be located at a side of the i-th intermediate signal transmission line 29i away from the N-th intermediate signal transmission line 29n, and the gate of the driving transistor M0 may be located at a side of the j-th intermediate signal transmission line 29j away from the first intermediate signal transmission line 291. In the direction perpendicular to the plane where the substrate is located, the gate device connection line 110 may be insulated and crossed from the i-th intermediate signal transmission line 29i to the j-th intermediate signal transmission line 29j. i may be a positive integer less than N, j may be a positive integer less than or equal to N, and j may be greater than i.

FIG. 32 is also a schematic diagram using N is 5 as an example, i is 3 and j is 5. Because the intermediate signal transmission lines may all be signal transmission lines 20 set between the first capacitor C1 and the second capacitor C2, the first intermediate signal transmission line 291 to the fifth intermediate signal transmission line 295 may be included between the first capacitor C1 and the second capacitor C2. The second terminal of the first transistor M1 may be located on the side of the third intermediate signal transmission line 293 away from the fifth intermediate signal transmission line 295, and the gate of the driving transistor M0 may be located on the side of the fifth intermediate signal transmission line 295 away from the first intermediate signal transmission line 291. The gate device connection line 110 may be insulated and crossed with the third intermediate signal transmission line 283 to the fifth intermediate signal transmission line 295 in the path connecting the second terminal of the first transistor M1 and the gate of the driving transistor M0, so that the number of signal transmission lines 20 having coupling interference with the gate device connection line 110 may be reduced, thereby ensuring that the potential stability at the gate of the driving transistor M0 is high. Thus, by setting a plurality of intermediate signal transmission lines at the middle area where the first partial circuit 11 and the second partial circuit 12 of the pixel driving circuit 10 are opposite, and some of the intermediate signal transmission lines may also pass through the inside of the first partial circuit 11 and the second partial circuit 12, the connection between the transistor and the signal transmission line 10 in the pixel driving circuit 10 may be simplified, and the line length of the device connection line 100 may be shortened, and the signal interference problem of other lines on the device connection line 100 may be reduced.

In addition, an edge signal transmission line may also be set in the edge direction of the pixel driving circuit 10 along the second direction Y, which may be more convenient for the connection between the signal transmission line 20 and the transistor in the pixel driving circuit 10. Further, referring to FIG. 32, along the direction from the first partial circuit 11 to the second partial circuit 12, the plurality of signal transmission lines 20 may include a first edge signal transmission line 296, a second edge signal transmission line 297, a third edge signal transmission line 298, a fourth edge signal transmission line 299, a first intermediate signal transmission line 291, a second intermediate signal transmission line 292, a third intermediate signal transmission line 293, a fourth intermediate signal transmission line 294, a fifth intermediate signal transmission line 295 and a fifth edge signal transmission line 2910 arranged in sequence. The first edge signal transmission line 296 to the fourth edge signal transmission line 299 may be located at the side of the first capacitor C1 away from the second partial circuit 12; the first intermediate signal transmission line 291 to the fifth intermediate signal transmission line 295 may be located between the first capacitor C1 and the second capacitor C2; and the fifth edge signal transmission line 2910 may be located at the side of the second partial circuit 12 away from the first part of the circuit 11. By optimizing the layout of the edge signal transmission lines and the middle signal transmission lines in the pixel driving circuit 10, the transistors at the edge and the transistors at the middle position in the pixel driving circuit 10 may be adjacent to their respective signal transmission lines 20, which may reduce the connection difficulty and distance between the signal transmission lines 20 and the transistors in the pixel driving circuit 10.

As shown in FIG. 29, the plurality of signal transmission lines 20 may include a first reference voltage line Vref1, a second reference voltage line Vref2, a first pulse width scanning control signal line PWMS1, a second pulse width scanning control signal line PWMS2, a first amplitude scanning control signal line PAMS1, a second amplitude scanning control signal line PAMS2, a first light-emission control signal line PWMK1, a second light-emission control signal line PAMK2, a turn-off voltage line Voff, and a pulse width control voltage line Sweep. As shown in FIG. 32, the first edge signal transmission line 296 may be the second reference voltage line Vref2, the second edge signal transmission line 297 may be the first pulse width scanning control signal line PWMS1, the third edge signal transmission line 298 may be the second pulse width scanning control signal line PWMS2, the fourth edge signal transmission line 299 may be the pulse width control voltage line Sweep, the first intermediate signal transmission line 291 may be the turn-off voltage line Voff, the second intermediate signal transmission line 292 may be the first light-emission control signal line PWMK1, the third intermediate signal transmission line 293 is the first reference voltage line Vref1, the fourth intermediate signal transmission line 294 may be the first amplitude scanning control signal line PAMS1, the fifth intermediate signal transmission line 295 may be the second amplitude scanning control signal line PAMS2, and the fifth edge signal transmission line 2910 may be the second light-emission control signal line PAMK2. Based on the distribution setting of the signal transmission line 20, the distribution of transistors and capacitors of the pulse width modulation unit 11 and the amplitude modulation unit 12 may be optimized to reduce the connection difficulty between the transistors and the signal transmission line 20.

In one embodiment, the pulse width modulation unit 11 may include a third transistor M3, a sixth transistor M6 and a fourth transistor M4 arranged in sequence along the first direction X, a second transistor M2 and a first capacitor C1 located at the side of the sixth transistor M6 facing the second circuit 12 and arranged in sequence along the first direction X, and a fifth transistor M5 and a first transistor M1 located at the side of the second transistor M2 facing the second circuit 12 and arranged in sequence along the first direction X. The turn-off voltage line Voff may be located at the side of the first light-emitting control signal line PWMK1 away from the second circuit 12, so that the turn-off voltage line Voff may be far away from the gate device connection line 110, and there may be no coupling crosstalk between the gate device connection line 110 and the turn-off voltage line Voff, thereby avoiding the turn-off voltage transmitted on the turn-off voltage line Voff from affecting the gate device connection line 110, thereby affecting the gate potential of the driving transistor M0.

As shown in FIG. 32, the amplitude modulation unit 12 may include a ninth transistor M9, an eighth transistor M8, a seventh transistor M7, and a twelfth transistor M12 arranged in sequence along the first direction X, a second capacitor C2 located at the side of the seventh transistor M7 facing the second light-emitting control signal line PAMK2, a driving transistor M0 located at the side of the second capacitor C2 facing the second light-emitting control signal line PAMK2, and a driving transistor M0 located at the side of the driving transistor M0 facing the second light-emitting control signal line PAMK2 and along the first direction X. The tenth transistor M10 and the eleventh transistor M11 may be arranged in sequence in the first direction X; the second terminal of the first transistor M1 may be located at the side of the first reference voltage line Vref1 toward the first light-emitting control signal line PWMK1, and the gate of the driving transistor M0 may be located at the side of the second capacitor C2 away from the second amplitude scanning control signal line PAMS2. It can be understood that the electrical connections between the transistors, capacitors and signal transmission lines 20 may be facilitated by arranging the electrically connected transistors, capacitors and signal transmission lines 20 nearby. For example, in the pulse width modulation unit 11, the first capacitor C1, the second transistor M2, the fourth transistor M4, the sixth transistor M6 and the third transistor M3 may be arranged nearby the first pulse width scanning control signal line PWMS1, the second pulse width scanning control signal line PWMS2, the pulse width control voltage line Sweep and the second reference voltage line Vref2, and the first transistor M1 and the fifth transistor M5 may be arranged nearby the first light-emitting control signal line PW MK1 and the turn-off voltage line Voff; and in the amplitude modulation unit 12, the seventh transistor M7 and the first reference voltage line Vref1 may be arranged nearby, the eighth transistor M8, the ninth transistor M9 and the twelfth transistor M12 may be arranged nearby the first reference voltage line Vref1, the first amplitude scanning control signal PAMS1 and the second amplitude scanning control signal line PAMS2, the driving transistor M0, the tenth transistor M10 and the second capacitor C2 may be arranged nearby, and the tenth transistor M10 and the eleventh transistor M11 may be arranged nearby the second light-emitting control signal line PAMK2.

Further, some transistors in the pixel driving circuit 10 may also be arranged to overlap with some signal transmission lines 20, which may not only reduce the wiring area of the pixel driving circuit 10 and the signal transmission line 20, but also reduce the film preparation and the preparation process flow by multiplexing some segments of the signal transmission line 20 by transistors. Further, referring to FIG. 32, in the orthographic projection on the substrate, in the pulse width modulation unit 11, the sixth transistor M6 may overlap with the first pulse width scanning control signal line PWMS1, the gate of the sixth transistor M6 may multiplex a portion of the line segment of the first pulse width scanning control signal line PWMS1, the second terminal of the sixth transistor M6 may be electrically connected to the second terminal of the first capacitor C1 through the first device connection line 121, and the first device connection line 121 may intersect with the second pulse width scanning control signal line PWMS2 and the pulse width control voltage line Sweep. The second terminal of the second transistor M2 may be electrically connected to the first terminal of the first transistor M1 through the second device connection line 122; the first transistor M1 may overlap with the first light-emitting control signal line PWMK1, the gate of the first transistor M1 may multiplex a portion of the line segment of the first light-emitting control signal line PWMK1, and the second device connection line 122 may intersect with the turn-off voltage Voff; the gate of the second transistor M2 and the connection terminal of the first capacitor C1 may be away from the signal transmission line 20, which may avoid the signal on the signal transmission line 20 from affecting the potential of the connection terminal, and ensure that the potential stability of the gate of the second transistor M2 may be substantially high. The third transistor M3 may overlap with the second pulse width scanning control signal line PWMS2, and the gate of the third transistor M3 may multiplex a portion of the line segment of the second pulse width scanning control signal line PWMS2. The fifth transistor M5 may overlap with the first light-emitting control signal line PWMK1, and the gate of the fifth transistor M5 may multiplex a portion of the line segment of the first light-emitting control signal line PWMK1. The second terminal of the third transistor M3 may be electrically connected to the second terminal of the fifth transistor M5 through the third device connection line 123, and the third device connection line 123 may cross both the turn-off voltage line Voff and the pulse width control voltage line Sweep. The second terminal of the fifth transistor M5 may be located at the side of the first light-emitting control signal line PWMK1 toward the second partial circuit 12, and the third device connection line 123 may also cross the first light-emitting control signal line PWMK1. The fourth transistor M4 may overlap with the second pulse width scanning control signal line PWMS2, the gate of the fourth transistor M4 may multiplex a portion of the second pulse width scanning control signal line PWMS2, the second terminal of the fourth transistor M4 may be electrically connected to the second terminal of the second transistor M2 through the fourth device connection line 124, and the fourth device connection line 124 may intersect with the pulse width control voltage line Sweep, the first capacitor C1 may extend to the side of the second transistor M2 facing the pulse width control voltage line Sweep, that is, the first capacitor C1 may be located in the area surrounded by the pulse width control voltage line Sweep, the fourth device connection line 124, the second transistor M2 and the third device connection line 123; and the first capacitor C1 may also include a portion extending between the second transistor M2 and the pulse width control voltage line Sweep to increase the area of the first capacitor C1, so as to better stabilize the potential of the terminal connected to the first capacitor C1.

Further, as shown in FIG. 32, in the amplitude modulation unit 12, the seventh transistor M7 may overlap with the first amplitude scanning control signal line PAMS1, and the gate of the seventh transistor M7 may multiplex a portion of the line segment of the first amplitude scanning control signal line PAMS1. The eighth transistor M8 may overlap with the second amplitude scanning control signal line PAMS2, and the gate of the eighth transistor M8 may multiplex a portion of the line segment of the second amplitude scanning control signal line PAMS2. The ninth transistor M9 may overlap with the second amplitude scanning control signal line PAMS2, and the gate of the ninth transistor M9 may multiplex a portion of the line segment of the second amplitude scanning control signal line PAMS2. The twelfth transistor M12 may overlap with the second amplitude scanning control signal line PAMS2, and the gate of the twelfth transistor M12 may multiplex a portion of the line segment of the second amplitude scanning control signal line PAMS2. The first terminal of the twelfth transistor M12 may be electrically connected to the first reference voltage line Vref1 through the fifth device connection line 125, and the fifth device connection line 125 may cross the first amplitude scanning control signal line PAMS1. The size of the second capacitor C2 in the first direction X may be not less than the size of the driving transistor M0 in the first direction X. The second capacitor C2 may be located between the driving transistor M0 and the second amplitude scanning control signal PAMS2 in the second direction Y, and the second capacitor C2 may be located between the device connection line 131 and the device connection line 132 in the first direction X. The device connection line 131 may be a connection line between the first terminal of the eighth transistor M8 and the second terminal of the driving transistor M0, and the device connection line 132 may be a connection line between the second terminal of the second transistor M12 and the second terminal of the eleventh transistor M11. In the first direction X, no transistor may be arranged in parallel with the second capacitor C2 to ensure that there may be enough wiring area to set the second capacitor C2, so that the area of the second capacitor C2 may be relatively large, so that the potential of the terminal connected to the second capacitor C2 may be better stabilized, especially the potential of the gate of the driving transistor M0, thereby improving the performance of the pixel driving circuit 10.

In some embodiments, the capacitance of the second capacitor C2 shown in FIG. 32 provided by the present disclosure may be set to be greater than the capacitance of the first capacitor C1, for example, the capacitance of the second capacitor C2 may be 1800 f, and the capacitance of the first capacitor C1 may be 1600 f, to stabilize the potential at the gate of the driving transistor M0 and the second transistor M2. In addition, the design that the capacitance of the second capacitor C2 shown in FIG. 32 may be greater than the capacitance of the first capacitor C1 may reduce the influence of the potential of the first terminal of the first transistor M1 on the potential at the gate of the driving transistor M0 when the first transistor M1 is turned on.

It should be noted that, in the display panel, the display panel may adopt a combination of at least one or more of the following overlapping methods: the sixth transistor M6 overlaps with the first pulse width scanning control signal line PWMS1, the first transistor M1 overlaps with the first light-emitting control signal line PWMK1, the third transistor M3 overlaps with the second pulse width scanning control signal line PWMS2, the fifth transistor M5 overlaps with the first light-emitting control signal line PWMK1, the fourth transistor M4 overlaps with the second pulse width scanning control signal line PWMS2, the seventh transistor M7 overlaps with the first amplitude scanning control signal line PAMS1, the eighth transistor M8 overlaps with the second amplitude scanning control signal line PAMS2, the ninth transistor M9 overlaps with the second amplitude scanning control signal line PAMS2, and the twelfth transistor M12 overlaps with the second amplitude scanning control signal line PAMS2. In addition, the device connection line 100 may be an integrated connection structure made of a same metal layer; or the device connection line 100 may be divided into multiple parts, different parts may be located in different metal layers, and different parts may be connected together by vias, such as the gate device connection line 110 shown in FIG. 32. The gate device connection line 110 may include a first part 111 and a second part 112. The first part 111 and the second part 112 may be located in different metal layers, and the first part 111 and the second part 112 may be connected as a connection line by a via 113 to electrically connect the second terminal of the first transistor M1 and the gate of the driving transistor M0. In addition, the device connection line 100 may directly connect the terminals of the two components, or the device connection line 100 may also connect the terminals of the two components indirectly. As shown in FIG. 32, the first part 111 of the gate device connection line 110 may be directly connected to the second terminal of the first transistor M1, and then the first part 111 may be connected to the second part 112 by a via 113, and the second part 112 may be connected to the second terminal of the second capacitor C2. Similarly, because the gate of the driving transistor M0 may be connected to the second terminal of the second capacitor C2, the second part 112 may be indirectly connected to the gate of the driving transistor M0 through the second terminal of the second capacitor C2.

In addition, the metal layer where different signal transmission lines 20 are located may be the same, for example, all signal transmission lines 20 may be formed through the gate metal layer 3. Alternatively, some of the signal transmission lines 20 may be formed using the gate metal layer 3, while some of the signal transmission lines 20 may be formed using the capacitor metal layer 6. For example, the first reference voltage line Vref1 and the second reference voltage line Vref2 may be formed using the capacitor metal layer 6, while the first pulse width scanning control signal line PWMS1, the second pulse width scanning control signal line PWMS2, the first amplitude scanning control signal line PAMS1, the second amplitude scanning control signal line PAMS2, the first light-emitting control signal line PWMK1, the second light-emitting control signal line PAMK2, the turn-off voltage line Voff and the pulse width control voltage line Sweep may be formed using the gate metal layer 3. In some embodiments, the first reference voltage line Vref1 may include a first sub-reference voltage line 2931 and a second sub-reference voltage line 2932, and the first sub-reference voltage line 2931 and the second sub-reference voltage line 2932 may be adjacent to each other. The second sub-reference voltage line 2931 may be located at the side of the first sub-reference voltage line 2932 facing the second part circuit 12. The first terminal of the twelfth transistor M12 may be electrically connected to the first sub-reference voltage line 2931 through the fifth device connection line 125, and the first terminal of the seventh transistor M7 may be electrically connected to the second sub-reference voltage line 2932. By setting two sub-reference voltage lines to transmit the first reference voltage to the seventh transistor M7 and the twelfth transistor M12 respectively, the load of the reference voltage line may be reduced. In the orthographic projection on the substrate, the fifth device connection line 125 may intersect with both the first amplitude scanning control signal line PAMS1 and the second sub-reference voltage line 2931. At this time, the first sub-reference voltage line 2931 and the second sub-reference voltage line 2932 may be formed by the gate metal layer 3 at the same time; or one of the first sub-reference voltage line 2931 and the second sub-reference voltage line 2932 may be formed by the gate metal layer 3, and the other may be formed by the capacitor metal layer 6.

As shown in FIG. 32, at the overlapping area of the device connection line 100 and the signal transmission line 20, at least one of the device connection line 100 and the signal transmission line 20 may be designed with a narrowed line width to reduce the coupling interference between the device connection line 100 and the signal transmission line 20. Specifically, at the overlapping area between the first device connection line 121 and the second pulse width scanning control signal line PWMS2 and the pulse width control voltage line Sweep, the line width of the first device connection line 121 may be designed to be narrowed; or at the overlapping area between the third device connection line 123 and the turn-off voltage line Voff and the first light-emitting control signal line PWMK1, the figure clearly shows that the line widths of the third device connection line 123, the turn-off voltage line Voff, and the first light-emitting control signal line PWMK1 are designed to be narrowed; or at the overlapping area between the gate device connection line 110 and the first sub-reference voltage line 2931, the line width of the first sub-reference voltage line 2931 may be designed to be narrowed, etc. Details may be combined with the overlapping areas of different device connection lines 100 and signal transmission lines 20 shown in FIG. 32. The so-called narrowing design may include that the line width of the first connection portion 101 may be smaller than the line width of the second connection portion 102, and the line width of the first transmission part 201 may be smaller than the line width of the second transmission portion 202, as described in any of the above embodiments, thereby realizing a design that reduces the overlapping area of the first connection portion 101 and the first transmission portion 201.

In addition, at the overlapping area of some device connection lines 100 and signal transmission lines 20, at least one of the device connection lines 100 and signal transmission lines 20 may also be designed with a hole to reduce the coupling interference between the device connection line 100 and the signal transmission line 20. For example, at the overlapping area of the device connection line 132 and the second light-emitting control signal line PAMK2, the second light-emitting control signal line PAMK2 may be designed with a hole to form a transmission hollowed hole 201a, thereby reducing the overlapping area of the device connection line 100 and the signal transmission line 20. It should be noted that the hole-forming design provided in the embodiment of the present disclosure is not limited to the overlapping area of the device connection line 132 and the second light-emitting control signal line PAMK2. The hole-forming design may also be performed at the overlapping area of other device connection lines 100 and signal transmission lines 20, and at least one of the device connection line 100 and the signal transmission line 20 may be formed with a hole, which may need to be specifically designed according to the actual application.

The display panel may also include a data voltage line having at least a portion of its line segments extending along the second direction Y, and the data voltage line may overlap with a portion of the signal transmission line 20. At the overlapping area of the data voltage line and the signal transmission line 20, at least one of the data voltage line and the signal transmission line 20 may be designed with narrowed line/or a hole to reduce the coupling crosstalk between the data voltage line and the signal transmission line 20. As shown in FIG. 32, the first partial circuit 11 may include a pulse width modulation unit of the pixel driving circuit 10, and the second partial circuit 12 may include an amplitude modulation unit of the pixel driving circuit 10. The pixel driving circuit 10 may include a first data voltage line D1 and a second data voltage line D2 extending along a second direction Y. The first data voltage line D1 may be electrically connected to the pulse width modulation unit 11, and the second data voltage line D2 may be electrically connected to the amplitude modulation unit 12 (specifically, reference may be made to the connection relationship between the data voltage lines D1 and D2 and the pixel driving circuit 10 shown in FIG. 29). The first data voltage line D1 may extend from the side of the first partial circuit 11 away from the second partial circuit 12 to the first partial circuit 11, and the first data voltage line D1 may overlap with at least one signal transmission line 20 in a direction perpendicular to the plane where the display panel is located. After the first data voltage line D1 crosses the second reference voltage line Vref2 and the first pulse width scanning control signal line PWMS1, it may be electrically connected to the first terminal of the third transistor M3. The first data voltage line D1 may be designed with a narrowed line width at the overlapped area with the second reference voltage line Vref2 and the first pulse width scanning control signal line PWMS1, thereby reducing the coupling interference between the first data voltage line D1 and the second reference voltage line Vref2 and the first pulse width scanning control signal line PWMS1. Also, the second data voltage line D2 may extend from the side of the second circuit 12 away from the first circuit 11 to the second circuit 12, and the second data voltage line D1 may overlap with at least one signal transmission line 20 in a direction perpendicular to the plane where the display panel is located, for example, the second data voltage line D2 may be electrically connected to the first terminal of the ninth transistor M9 after crossing the second light-emitting control signal line PAMK2 and the second amplitude scanning control signal line PAMS2, and the second data voltage line D2 may be designed with a narrowed line width at the overlapped area with the second light-emitting control signal line PAMK2 and the second amplitude scanning control signal line PAMS2, thereby reducing the coupling interference between the second data voltage line D2 and the second light-emitting control signal line PAMK2 and the second amplitude scanning control signal line PAMS2.

In another embodiment, referring to another data voltage line design shown in FIG. 31, the first data voltage line D1 and the second data voltage line D2 may both pass through the first partial circuit 11 and the second partial circuit 12. The first data voltage line D1 and the second data voltage line D2 may both overlap with at least one signal transmission line 20 in a direction perpendicular to the plane where the display panel is located. Similarly, at the overlapping area of the data voltage line and the signal transmission line 20, at least one of the data voltage line and the signal transmission line 20 may be designed with a narrowed line width/or a hole to reduce the coupling crosstalk between the data voltage line and the signal transmission line 20. In addition, in the extension direction of the data voltage line, when the data voltage line and the via are on the same path, the data voltage line may be designed with a winding line, such as the first data voltage line D1 and the via 130 shown in FIG. 31, where the first data voltage line D1 may be designed with a winding line. In one embodiment of the present disclosure, the data voltage line may be arranged in the same layer as the device connection line 100, and the present disclosure does not make any specific restrictions on this.

In any of the above embodiments of the present disclosure, the transistors in the pixel driving circuit 10 may all be N-type transistors; or all be P-type transistors; or some may be N-type transistors and some may be P-type transistors, which may need to be specifically designed according to the actual application.

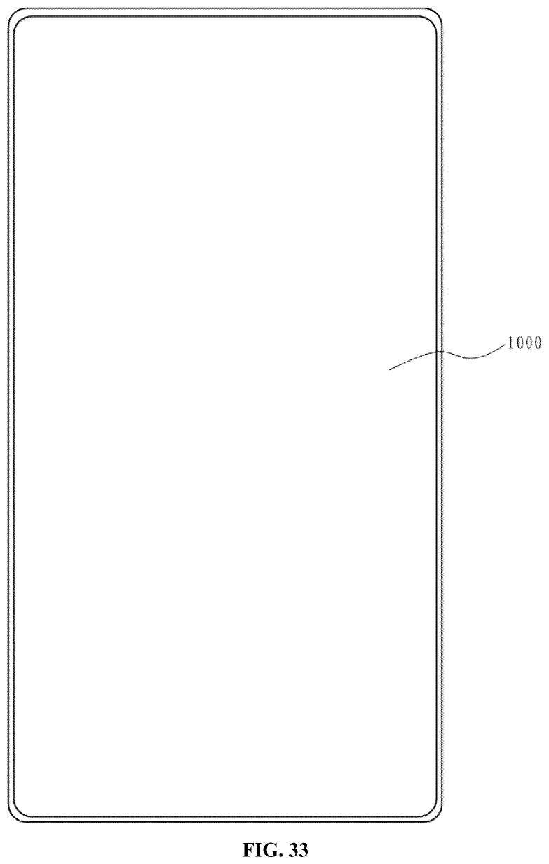

The present disclosure also provides an electronic device. The electronic device may include a display panel provided in any of the above embodiments. As shown in FIG. 33, the electronic device 1000 provided in one embodiment of the present disclosure may be a mobile terminal, which may include a display panel provided in any of the above embodiments. It should be noted that the electronic device provided in the embodiment of the present disclosure may also be a notebook, a tablet computer, a computer, a wearable device, etc., and the present disclosure does not make specific restrictions on this.

The embodiment of the present disclosure provides a display panel and an electronic device. The display panel may include a pixel driving circuit. The pixel driving circuit may include a driving transistor and a first transistor. One terminal of the first transistor may be connected to the gate of the driving transistor via a gate device connection line. The display panel may also include a plurality of signal transmission lines. The signal transmission lines may provide control signals or input signals for the pixel driving circuit, and the signal transmission lines may extend along a first direction. The gate device connection line may include a first connection line portion extending along a second direction. The first connection line portion may at least partially overlap with at least two signal transmission lines in a direction perpendicular to the plane where the display panel is located; and the first direction and the second direction may intersect. Thus, by optimizing the circuit layout of the pixel driving circuit, the electrical connection between the components of the pixel driving circuit and the signal transmission line may be facilitated, the signal transmission effect may be ensured to be high, and the performance of the display panel may be improved.

In the description of the embodiments of the present disclosure, it should be understood that the orientation or position relationship indicated by the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, or “circumferential”, etc. is based on the orientation or position relationship shown in the drawings, which is only for the convenience of describing the embodiments of the present disclosure and simplifying the description, rather than indicating or implying that the device or element referred to must have a specific orientation, be constructed and operated in a specific orientation, and therefore cannot be understood as a limitation of the present application.

In addition, the terms “first” and “second” are only used for descriptive purposes and cannot be understood as indicating or implying relative importance or implicitly indicating the number of technical features indicated. Therefore, the features defined as “first” and “second” may explicitly or implicitly include at least one such feature. In the description of the embodiments of the present application, the meaning of “multiple” is at least two, such as two, three, etc., unless otherwise clearly and specifically defined.

In the embodiments of the present disclosure, unless otherwise clearly specified and limited, the terms “installed”, “connected”, and “fixed” and the like should be understood in a broad sense, for example, they can be fixedly connected, detachably connected, or integrated; they can be mechanically connected, electrically connected, or can communicate with each other; they can be directly connected, or indirectly connected through an intermediate medium, or they can be internally connected between two elements or the interaction relationship between two elements, unless otherwise clearly specified. For ordinary technicians in this field, the specific meanings of the above terms in this disclosure can be understood according to the specific circumstances.

In the embodiments of the present disclosure, unless otherwise clearly specified and limited, the first feature “above” or “below” the second feature can be that the first and second features are in direct contact, or the first and second features are in indirect contact through an intermediate medium. Moreover, the first feature “above”, and “on” the second feature can mean that the first feature is directly above or obliquely above the second feature, or simply means that the first feature is higher in level than the second feature. The first feature “below”, and “under” the second feature can mean that the first feature is directly below or obliquely below the second feature, or simply means that the first feature is lower in level than the second feature.

In the embodiments of the present disclosure, if the terms “one embodiment”, “some embodiments”, “example”, “specific example”, or “some examples” appear, it means that the specific features, structures, materials or characteristics described in conjunction with the embodiment or example are included in at least one embodiment or example of the present disclosure. In this specification, the schematic representation of the above terms does not necessarily refer to the same embodiment or example. Moreover, the specific features, structures, materials or characteristics described can be combined in any one or more embodiments or examples in a suitable manner. In addition, those skilled in the art can combine and combine different embodiments or examples described in this specification and the features of different embodiments or examples without contradiction.

Although the embodiments of the present disclosure have been shown and described above, it can be understood that the above embodiments are exemplary and cannot be understood as limitations on the present application. Those of ordinary skill in the art can change, modify, replace and modify the above embodiments within the scope of the present application.

What is claimed is:

1. A display panel, comprising:
a pixel driving circuit, including a driving transistor and a first transistor, one terminal of the first transistor being connected to a gate of the driving transistor through a gate device connection line; and
a plurality of signal transmission lines providing control signals or input signals for the pixel driving circuit,
wherein:
a signal transmission line of the plurality of signal transmission lines extends in a first direction;
the gate device connection line includes a first connection line portion extending in a second direction;
in a direction perpendicular to a plane where the display panel is located, the first connection line portion at least partially overlaps with at least two signal transmission lines of the plurality of signal transmission line; and
the first direction intersects with the second direction.

2. The display panel according to claim 1, comprising:
a substrate,
wherein:
the pixel driving circuit is located on the substrate;
the pixel driving circuit includes a first partial circuit and a second partial circuit arranged opposite to each other in the second direction;
the plurality of signal transmission lines comprises at least two first intermediate signal transmission lines located between the first partial circuit and the second partial circuit;
the first transistor is located in the first partial circuit;
the driving transistor is located in the second partial circuit; and
the first connection line portion of the gate device connection line at least partially overlaps with the at least two first intermediate signal transmission lines.

3. The display panel according to claim 2, wherein the first partial circuit comprises:
a first capacitor,
wherein:
the plurality of signal transmission lines also include at least one second intermediate signal transmission line located between the at least two first intermediate signal transmission lines and the first capacitor, and an orthographic projection of at least one transistor in the first partial circuit on the substrate at least partially overlaps with an orthographic projection of the second intermediate signal transmission line on the substrate; and/or,
the second partial circuit includes a second capacitor, and the plurality of signal transmission lines also include at least one third intermediate signal transmission line located between the at least two first intermediate signal transmission lines and the second capacitor, and an orthographic projection of at least one transistor in the second partial circuit on the substrate at least partially overlaps with an orthographic projection of the third intermediate signal transmission line on the substrate.

4. The display panel according to claim 3, wherein:
at an overlapping area of the transistor in the first partial circuit and the second intermediate signal transmission line, and/or at an overlapping area of the transistor in the second partial circuit and the third intermediate signal transmission line, a gate of a transistor multiplexes a portion of a line segment of a corresponding intermediate signal transmission line.

5. The display panel according to claim 2, wherein:
the plurality of signal transmission lines also include at least one first edge signal transmission line located at a side of the first partial circuit away from the second partial circuit; and/or
the plurality of signal transmission lines also include at least one second edge signal transmission line located on a side of the second partial circuit away from the first partial the circuit.

6. The display panel according to claim 5, wherein:
the first partial circuit includes a first capacitor, and the plurality of signal transmission lines also include a third edge signal transmission line located between the at least one first edge signal transmission line and the first capacitor, and an orthographic projection of at least one transistor in the first partial circuit on the substrate at least partially overlaps with an orthographic projection of the third edge signal transmission line on the substrate; and/or
the second partial circuit includes a second capacitor, and the plurality of signal transmission lines also include a fourth edge signal transmission line located between the at least one second edge signal transmission line and the second capacitor; and an orthographic projection of at least one transistor in the second partial circuit on the substrate at least partially overlaps with an orthographic projection of the fourth edge signal transmission line on the substrate.

7. The display panel according to claim 6, wherein:
at an overlapping area of a transistor in the first partial circuit and the third edge signal transmission line, and/or at an overlapping area of a transistor in the second partial circuit and the fourth edge signal line, a gate of the transistor multiplexes a portion of a line segment of a corresponding edge signal transmission line.

8. The display panel according to claim 1, wherein:
the pixel driving circuit includes a plurality of device connection lines;
the plurality of device connection lines include the gate device connection line;
at least one device connection line includes at least one first connection line portion extending along the second direction;
the at least one device connection line also includes a second connection line portion;
at least one of the plurality of signal transmission lines includes a first transmission line portion and a second transmission line portion;
in a direction perpendicular to a plane where the display panel is located, at least one first connection line portion overlaps with at least one first transmission line portion;
the first connection line portion of the gate device connection line overlaps with at least two first transmission line portions; and
at least in an overlapping area of the first connection line portion and the first transmission line portion, a line width of the first connection line portion is smaller than a line width of the second connection line portion, and/or a line width of the first transmission line portion is smaller than a line width of the second transmission line portion.

9. The display panel according to claim 8, wherein:
the line width of the first connection line portion is smaller than the line width of the second connection line portion, the device connection line further includes a third connection line portion, and a line width of the third connection line portion is greater than the line width of the second connection line portion; and/or
the line width of the first connection line portion is smaller than the line width of the second connection line portion, the device connection line further includes a parallel connection line portion, and the parallel connection line portion is connected in parallel with the second connection line portion; and/or
the line width of the first transmission line portion is smaller than the line width of the second transmission line portion, and the signal transmission line further includes a third transmission line portion, and a line width of the third transmission line portion is greater than the line width of the second transmission line portion; and/or,
the line width of the first transmission line portion is smaller than the line width of the second transmission line portion, and the signal transmission line further includes a parallel transmission line portion, and the parallel transmission line portion is connected in parallel with the second transmission line portion.

10. The display panel according to claim 9, wherein:
the parallel connection line portion and the second connection line portion are arranged in a same layer, or the parallel connection line portion and the second connection line portion are arranged in different layers, and in the direction perpendicular to the plane where the display panel is located, the parallel connection line portion and the second connection line portion at least partially overlap in an extension direction; and
the parallel transmission line portion and the second transmission line portion are arranged in a same layer, or the parallel transmission line portion and the second transmission line portion are arranged in different layers, and in the direction perpendicular to the plane where the display panel is located, the parallel transmission line portion and the second transmission line portion at least partially overlap in the extension direction.

11. The display panel according to claim 1, wherein:
the pixel driving circuit includes a plurality of device connection lines, the plurality of device connection lines include the gate device connection line, at least one device connection line includes at least a first connection line portion extending in the second direction, the at least one device connection line also includes a second connection line portion, at least one signal transmission line includes a first transmission line portion and a second transmission line portion, in a direction perpendicular to the plane where the display panel is located, at least one first connection line portion overlaps with at least one first transmission line portion, and the first connection line portion of the gate device connection line overlaps with at least two first transmission line portions; and
at an overlapping area of the first connection line portion and the first transmission line portion, the first connection line portion includes at least one connection hollowed hole overlapping with the first transmission line portion, and/or the first transmission line portion includes at least one transmission hollowed hole overlapping with the first connection line portion.

12. The display panel according to claim 11, wherein:
in the second direction, a width of the connection hollowed hole is greater than the width of the first transmission line portion, and orthographic projections of inner walls on both sides of the connection hollowed hole on the substrate are both located outside an orthographic projection of the first transmission line portion on the substrate; and
in the first direction, a width of the transmission hollowed hole is greater than the width of the first connection line portion, and orthographic projections of inner walls on both sides of the transmission hollowed hole on the substrate are both located outside an orthographic projection of the first connection line portion on the substrate.

13. The display panel according to claim 3, wherein:
the first partial circuit includes a pulse width modulation unit of the pixel driving circuit, the second partial circuit includes an amplitude modulation unit of the pixel driving circuit, the pulse width modulation unit includes the first transistor, the amplitude modulation unit includes the driving transistor, a second terminal of the first transistor is electrically connected to the gate of the driving transistor through the gate device connection line;
in a direction from the first partial circuit to the second partial circuit, all the second intermediate signal transmission line, the first intermediate signal transmission line and the third intermediate signal transmission line are defined as a first intermediate signal transmission line to an N-th intermediate signal transmission line arranged in sequence, and N is an integer greater than or equal to 2; and
the second terminal of the first transistor is located at a side of an i-th intermediate signal transmission line away from the N-th intermediate signal transmission line, the gate of the driving transistor is located at a side of a j-th intermediate signal transmission line away from the first intermediate signal transmission line, in the direction perpendicular to the plane where the display panel is located, the gate device connection line is insulated and crossed with the i-th intermediate signal transmission line to the j-th intermediate signal transmission line, i is a positive integer less than N, j is a positive integer less than or equal to N, and j is greater than i.

14. The display panel according to claim 13, wherein:
in the direction from the first partial circuit to the second partial circuit, the plurality of signal transmission lines include a first edge signal transmission line, a second edge signal transmission line, a third edge signal transmission line, a fourth edge signal transmission line, a first intermediate signal transmission line, a second intermediate signal transmission line, a third intermediate signal transmission line, a fourth intermediate signal transmission line, a fifth intermediate signal transmission line and a fifth edge signal transmission line arranged in sequence;
the first edge signal transmission line to the fourth edge signal transmission line are located on a side of the first capacitor away from the second partial circuit;
the first intermediate signal transmission line to the fifth intermediate signal transmission line are located between the first capacitor and the second capacitor; and
the fifth edge signal transmission line is located on a side of the second partial circuit away from the first partial circuit.

15. The display panel according to claim 14, wherein:
the first edge signal transmission line is a second reference voltage line, the second edge signal transmission line is a first pulse width scanning control signal line, the third edge signal transmission line is a second pulse width scanning control signal line, the fourth edge signal transmission line is a pulse width control voltage line, the first intermediate signal transmission line is a turn-off voltage line, the second intermediate signal transmission line is a first light-emitting control signal line, the third intermediate signal transmission line is a first reference voltage line, the fourth intermediate signal transmission line is a first amplitude scanning control signal line, the fifth intermediate signal transmission line is a second amplitude scanning control signal line, and the fifth edge signal transmission line is a second light-emitting control signal line;
the pulse width modulation unit includes a third transistor, a sixth transistor, and a fourth transistor arranged in sequence along the first direction, a second transistor and a first capacitor located at a side of the sixth transistor facing the second partial circuit and arranged in sequence along the first direction, and a fifth transistor and a first transistor located at a side of the second transistor facing the second partial circuit and arranged in sequence along the first direction;
the amplitude modulation unit includes a ninth transistor, an eighth transistor, a seventh transistor and a twelfth transistor arranged in sequence along the first direction, the second capacitor located on a side of the seventh transistor facing the second light-emitting control signal line, the driving transistor located on a side of the second capacitor facing the second light-emitting control signal line, and a tenth transistor and an eleventh transistor located at a side of the driving transistor facing the second light-emitting control signal line and arranged in sequence along the first direction; and
a second terminal of the first transistor is located at a side of the first reference voltage line facing the first light-emitting control signal line, and the gate of the driving transistor is located at a side of the second capacitor away from the second amplitude scanning control signal line.

16. The display panel according to claim 15, wherein in an orthographic projection on the substrate, wherein:
the sixth transistor overlaps with the first pulse width scanning control signal line, a second terminal of the sixth transistor is electrically connected to a second terminal of the first capacitor through the first device connection line, and the first device connection line crosses the second pulse width scanning control signal line and the pulse width control voltage line; and/or
a second terminal of the second transistor is electrically connected to the first terminal of the first transistor through the second device connection line, the first transistor overlaps with the first light-emitting control signal line, and the second device connection line crosses the turn-off voltage line; and/or
the third transistor overlaps with the second pulse width scanning control signal line, the fifth transistor overlaps with the first light-emitting control signal line, a second terminal of the third transistor is electrically connected to a second terminal of the fifth transistor through the third device connection line, and the third device connection line crosses both the turn-off voltage line and the pulse width control voltage line; and/or
the fourth transistor is electrically connected to the second pulse width scanning control signal line, a second terminal of the fourth transistor overlaps with the second terminal of the second transistor through the fourth device connection line, and the fourth device connection line crosses the pulse width control voltage line; and/or
the first capacitor extends to a side the second transistor facing the pulse width control voltage line; and/or
the seventh transistor overlaps with the first amplitude scanning control signal line; and/or
the eighth transistor overlaps with the second amplitude scanning control signal line; and/or
the ninth transistor overlaps with the second amplitude scanning control signal line; and/or
the twelfth transistor overlaps with the second amplitude scanning control signal line, a first terminal of the twelfth transistor is electrically connected to the first reference voltage line through the fifth device connection line, and the fifth device connection line crosses the first amplitude scanning control signal line; and/or
a size of the second capacitor in the first direction is not less than a size of the driving transistor in the first direction.

17. The display panel according to claim 16, wherein:
the first reference voltage line includes a first sub-reference voltage line and a second sub-reference voltage line;
the second sub-reference voltage line is located at a side of the first sub-reference voltage line facing the second partial circuit;
the first terminal of the twelfth transistor is electrically connected to the first sub-reference voltage line through the fifth device connection line; and
in an orthographic projection on the substrate, the fifth device connection line crosses both the first amplitude scanning control signal line and the second sub-reference voltage line.

18. The display panel according to claim 3, wherein:
the first partial circuit includes a pulse width modulation unit of the pixel driving circuit, the second partial circuit includes an amplitude modulation unit of the pixel driving circuit, the pulse width modulation unit includes the first transistor, the amplitude modulation unit includes the driving transistor, and a second terminal of the first transistor is electrically connected to the gate of the driving transistor through a gate device connection line;
in a direction from the first partial circuit to the second partial circuit, all the second intermediate signal transmission line, the first intermediate signal transmission line and the third intermediate signal transmission line are defined as a first intermediate signal transmission line to an N-th intermediate signal transmission line arranged in sequence, and N is an integer greater than or equal to 2; and
the second terminal of the first transistor is located at a side of the first intermediate signal transmission line away from the N-th intermediate signal transmission line, and the gate of the driving transistor is located at a side of the N-th intermediate signal transmission line away from the first intermediate signal transmission line; wherein, in a direction perpendicular to the plane where the display panel is located, the gate device connection line is insulated and crossed with the first intermediate signal transmission line to the N-th intermediate signal transmission line.

19. The display panel according to claim 18, wherein:
in the direction from the first partial circuit to the second partial the circuit, the plurality of signal transmission lines include a first edge signal transmission line, a second edge signal transmission line, a third edge signal transmission line, a fourth edge signal transmission line, a first intermediate signal transmission line, a second intermediate signal transmission line, a third intermediate signal transmission line, a fourth intermediate signal transmission line, a fifth intermediate signal transmission line and a fifth edge signal transmission line arranged in sequence; and
the first edge signal transmission line to the fourth edge signal transmission line are located at a side of the first capacitor away from the second partial circuit, the first intermediate signal transmission line to the fifth intermediate signal transmission line are located between the first capacitor and the second capacitor, and the fifth edge signal transmission line is located at a side of the second partial circuit away from the first partial circuit.

20. The display panel according to claim 19, wherein:
the first edge signal transmission line is a second reference voltage line, the second edge signal transmission line is a first pulse width scanning control signal line, the third edge signal transmission line is a second pulse width scanning control signal line, the fourth edge signal transmission line is a pulse width control voltage line, the first intermediate signal transmission line is a first light-emitting control signal line, the second intermediate signal transmission line is a turn-off voltage line, the third intermediate signal transmission line is a first reference voltage line, the fourth intermediate signal transmission line is a first amplitude scanning control signal line, the fifth intermediate signal transmission line is a second amplitude scanning control signal line, and the fifth edge signal transmission line is a second light-emitting control signal line;
the pulse width modulation unit includes a fourth transistor, a sixth transistor and a third transistor arranged in sequence in the first direction, the first capacitor located at a side of the sixth transistor facing the second circuit partial circuit, a second transistor located at a side of the capacitor facing the second partial circuit, and a first transistor and a fifth transistor located at the side of the second transistor facing the second partial circuit and arranged in sequence in the first direction; and
the amplitude modulation unit includes a seventh transistor, a twelfth transistor, an eighth transistor and a ninth transistor located at a side of the seventh transistor facing the second light-emitting control signal line and arranged in sequence along the first direction, an eleventh transistor and the driving transistor located at a side of the eighth transistor facing the second light-emitting control signal line and arranged in sequence along the first direction, and the second capacitor and a tenth transistor are located at the side of the driving transistor facing the second light-emitting control signal line and arranged in sequence along the first direction.

21. The display panel according to claim 20, wherein in an orthographic projection on the substrate wherein:
the sixth transistor overlaps with the first pulse width scanning control signal line, and the first capacitor extends to between the second pulse width scanning control signal line and the pulse width control voltage line, a second terminal of the sixth transistor is electrically connected to a second terminal of the first capacitor through the sixth device connection line, and the sixth device connection line at least crosses the second pulse width scanning control signal line; and/or
the third transistor overlaps with the second pulse width scanning control signal line, a second terminal of the third transistor is electrically connected to the first terminal of the second transistor through the seventh device connection line, and the seventh device connection line crosses the pulse width control voltage line; and/or
the fourth transistor overlaps with the second pulse width scanning control signal line, a second terminal of the fourth transistor is electrically connected to the second terminal of the second transistor through the eighth device connection line, and the eighth device connection line crosses the pulse width control voltage line; and/or
the seventh transistor overlaps with the first amplitude scanning control signal line; and/or
at least one of the eighth transistor, the ninth transistor and the twelfth transistor overlaps with the second amplitude scanning control signal line.

22. The display panel according to claim 2, wherein:
the first partial circuit includes a pulse width modulation unit of the pixel driving circuit, and the second partial circuit includes an amplitude modulation unit of the pixel driving circuit, wherein the pixel driving circuit includes a first data voltage line and a second data voltage line extending along the second direction, the first data voltage line is electrically connected to the pulse width modulation unit, and the second data voltage line is electrically connected to the amplitude modulation unit;
the first data voltage line extends from a side of the first partial circuit away from the second partial circuit to the first partial circuit, and the first data voltage line overlaps with at least one signal transmission line in a direction perpendicular to the plane where the display panel is located, and the second data voltage line extends from a side of the second partial circuit away from the first partial circuit to the second partial circuit, and the second data voltage line overlaps with at least one signal transmission line in a direction perpendicular to the plane where the display panel is located; or
both the first data voltage line and the second data voltage line pass through the first partial circuit and the second partial circuit, and both the first data voltage line and the second data voltage line overlap with at least one signal transmission line in a direction perpendicular to the plane where the display panel is located.

23. An electronic device, comprising:
a display panel, including:
a pixel driving circuit, wherein the pixel driving circuit includes a driving transistor and a first transistor, and one terminal of the first transistor is connected to a gate of the driving transistor through a gate device connection line; and
a plurality of signal transmission lines providing control signals and/or input signals for the pixel driving circuit,
wherein:
a signal transmission line of the plurality of signal transmission lines extends in a first direction;
the gate device connection line includes a first connection line portion extending in a second direction;
in a direction perpendicular to a plane where the display panel is located, the first connection line portion at least partially overlaps with at least two signal transmission lines of the plurality of signal transmission line; and
the first direction intersects with the second direction.
